(19) United States
(12) Patent Application Publication
(10) Pub. No.: US 2026/0059797 A1
(43) Pub. Date: Feb. 26, 2026

(54) EPITAXIAL REGION CONTACT STRUCTURE

(71) Applicant: International Business Machines Corporation, Armonk, NY (US)

(72) Inventors: Minhaz Abedin, Delmar, NY (US); Shahrukh Khan, Sandy Hook, CT (US); Mohammad Hasanuzzaman, Niskayuna, NY (US); Mohamed Abdelmaksoud Mohamed Rabie, Clifton Park, NY (US); Ruilong Xie, Niskayuna, NY (US); Oleg Gluschenkov, Tannersville, NY (US); Utkarsh Bajpai, Delmar, NY (US)

(21) Appl. No.: 18/814,024

(22) Filed: Aug. 23, 2024

(51) Int. Cl. H01L 29/417; H01L 27/088; H01L 29/06; H01L 29/423; H01L 29/775; H01L 29/786

(52) U.S. Cl. CPC H10D 30/6729; H10D 84/83; H10D 30/43; H10D 30/6735; H10D 30/6757; H10D 62/121

(57) ABSTRACT

A semiconductor device includes a first transistor including a first drain region, and a second transistor including a second drain region, wherein in the second transistor is stacked over the first transistor. A contact structure is disposed through the second drain region, wherein the contact structure contacts the first drain region.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower costs. Present technology is at or approaching atomic level scaling of certain micro-devices such as logic gates, field-effect transistors (FETs), and capacitors.

### SUMMARY

Embodiments of the invention provide structures for and techniques for forming epitaxial region contact structures for FETs.

In one embodiment, a semiconductor device includes a first transistor including a first drain region, and a second transistor including a second drain region, wherein the second transistor is stacked over the first transistor. A contact structure is disposed through the second drain region, wherein the contact structure contacts the first drain region.

In another embodiment, a semiconductor device includes a first field-effect transistor including a first epitaxial region, a second field-effect transistor including a second epitaxial region, wherein in the second epitaxial region is stacked over the first epitaxial region, and a contact structure disposed through the second epitaxial region, wherein the contact structure is connected to the first epitaxial region.

In another embodiment, a semiconductor device includes at least one field-effect transistor including a source region and a drain region, and a contact structure disposed in at least one of the source region and the drain region. The contact structure includes at least one conductive material, and the source region and the drain region respectively comprise epitaxial layers.

These and other features and advantages of embodiments described herein will become more apparent from the accompanying drawings and the following detailed description.

### BRIEF DESCRIPTION OF THE DRAWINGS

FIG. 1 depicts a top view of a semiconductor structure with lines X and Y on which the cross-sectional views of FIGS. 2-11 are based, according to an embodiment of the invention.

FIG. 2 depicts a first cross-sectional view corresponding to the line X in FIG. 1 illustrating semiconductor nanosheet layers and nanosheet patterning, according to an embodiment of the invention.

FIG. 3 depicts a second cross-sectional view corresponding to the line Y in FIG. 1 illustrating semiconductor nanosheet layers and nanosheet patterning, according to an embodiment of the invention.

FIG. 4 depicts first cross-sectional view corresponding to the line X in FIG. 1 illustrating dummy gate formation, according to an embodiment of the invention.

FIG. 5 depicts second cross-sectional view corresponding to the line Y in FIG. 1 illustrating dummy gate formation, according to an embodiment of the invention.

FIG. 6 depicts a first cross-sectional view corresponding to the line X in FIG. 1 following gate spacer formation, and middle dielectric insulator layer (MDI) formation, according to an embodiment of the invention.

FIG. 7 depicts a second cross-sectional view corresponding to the line Y in FIG. 1 following gate spacer formation, and MDI formation, according to an embodiment of the invention.

FIG. 8 depicts a first cross-sectional view corresponding to the line X in FIG. 1 following lateral recessing of sacrificial semiconductor layers, inner spacer formation, and placeholder formation, according to an embodiment of the invention.

FIG. 9 depicts a second cross-sectional view corresponding to the line Y in FIG. 1 following lateral recessing of sacrificial semiconductor layers, inner spacer formation, and placeholder formation, according to an embodiment of the invention.

FIG. 10 depicts a first cross-sectional view corresponding to the line X in FIG. 1 following source/drain region formation, according to an embodiment of the invention.

FIG. 11 depicts a second cross-sectional view corresponding to the line Y in FIG. 1 following source/drain region formation, according to an embodiment of the invention.

FIG. 12 depicts a top view of a semiconductor structure with lines X, Y and S on which the cross-sectional views of FIGS. 13-15 are based, according to an embodiment of the invention.

FIG. 13 depicts a first cross-sectional view corresponding to the line X in FIG. 12 following inter-layer dielectric (ILD) layer formation, replacement metal gate (RMG) formation, and patterning for via formation, according to an embodiment of the invention.

FIG. 14 depicts a second cross-sectional view corresponding to the line S in FIG. 12 following ILD layer formation, RMG formation, and patterning for via formation, according to an embodiment of the invention.

FIG. 15 depicts a third cross-sectional view corresponding to the line Y in FIG. 12 following ILD layer formation, RMG formation, and patterning for via formation, according to an embodiment of the invention.

FIG. 16 depicts a top view of a semiconductor structure with lines X, Y and S on which the cross-sectional views of FIGS. 17-48 are based, according to an embodiment of the invention.

FIG. 17 depicts a first cross-sectional view corresponding to the line X in FIG. 16 following via formation and patterning of a drain region for an epitaxial region contact structure, according to an embodiment of the invention.

FIG. 18 depicts a second cross-sectional view corresponding to the line S in FIG. 16 following via formation and patterning of a drain region for an epitaxial region contact structure, according to an embodiment of the invention.

FIG. 19 depicts a third cross-sectional view corresponding to the line D in FIG. 16 following via formation and patterning of a drain region for an epitaxial region contact structure, according to an embodiment of the invention.

FIG. 20 depicts a fourth cross-sectional view corresponding to the line Y in FIG. 16 following via formation and patterning of a drain region for an epitaxial region contact structure, according to an embodiment of the invention.

FIG. 21 depicts a first cross-sectional view corresponding to the line X in FIG. 16 following spacer etch-back, according to an embodiment of the invention.

FIG. 22 depicts a second cross-sectional view corresponding to the line S in FIG. 16 following spacer etch-back, according to an embodiment of the invention.

FIG. 23 depicts a third cross-sectional view corresponding to the line D in FIG. 16 following spacer etch-back, according to an embodiment of the invention.

FIG. 24 depicts a fourth cross-sectional view corresponding to the line Y in FIG. 16 following spacer etch-back, according to an embodiment of the invention.

FIG. 25 depicts a first cross-sectional view corresponding to the line X in FIG. 16 following bottom epitaxial block material deposition and recessing, according to an embodiment of the invention.

FIG. 26 depicts a second cross-sectional view corresponding to the line S in FIG. 16 following bottom epitaxial block material deposition and recessing, according to an embodiment of the invention.

FIG. 27 depicts a third cross-sectional view corresponding to the line D in FIG. 16 following bottom epitaxial block material deposition and recessing, according to an embodiment of the invention.

FIG. 28 depicts a fourth cross-sectional view corresponding to the line Y in FIG. 16 following bottom epitaxial block material deposition and recessing, according to an embodiment of the invention.

FIG. 29 depicts a first cross-sectional view corresponding to the line X in FIG. 16 following spacer etch-back, according to an embodiment of the invention.

FIG. 30 depicts a second cross-sectional view corresponding to the line S in FIG. 16 following spacer etch-back, according to an embodiment of the invention.

FIG. 31 depicts a third cross-sectional view corresponding to the line D in FIG. 16 following spacer etch-back, according to an embodiment of the invention.

FIG. 32 depicts a fourth cross-sectional view corresponding to the line Y in FIG. 16 following spacer etch-back, according to an embodiment of the invention.

FIG. 33 depicts a first cross-sectional view corresponding to the line X in FIG. 16 following frontside gate contact formation, frontside source/drain contact formation and epitaxial region contact structure formation, according to an embodiment of the invention.

FIG. 34 depicts a second cross-sectional view corresponding to the line S in FIG. 16 following frontside gate contact formation, frontside source/drain contact formation and epitaxial region contact structure formation, according to an embodiment of the invention.

FIG. 35 depicts a third cross-sectional view corresponding to the line D in FIG. 16 following frontside gate contact formation, frontside source/drain contact formation and epitaxial region contact structure formation, according to an embodiment of the invention.

FIG. 36 depicts a fourth cross-sectional view corresponding to the line Y in FIG. 16 following frontside gate contact formation, frontside source/drain contact formation and epitaxial region contact structure formation, according to an embodiment of the invention.

FIG. 37 depicts a first cross-sectional view corresponding to the line X in FIG. 16 following back-end-of-line (BEOL) interconnect formation and carrier wafer bonding, according to an embodiment of the invention.

FIG. 38 depicts a second cross-sectional view corresponding to the line S in FIG. 16 following BEOL interconnect formation and carrier wafer bonding, according to an embodiment of the invention.

FIG. 39 depicts a third cross-sectional view corresponding to the line D in FIG. 16 following BEOL interconnect formation and carrier wafer bonding, according to an embodiment of the invention.

FIG. 40 depicts a fourth cross-sectional view corresponding to the line Y in FIG. 16 following BEOL interconnect formation and carrier wafer bonding, according to an embodiment of the invention.

FIG. 41 depicts a first cross-sectional view corresponding to the line X in FIG. 16 following wafer flipping, semiconductor substrate removal, backside ILD layer formation and planarization, according to an embodiment of the invention.

FIG. 42 depicts a second cross-sectional view corresponding to the line S in FIG. 16 following wafer flipping, semiconductor substrate removal, backside ILD layer formation and planarization, according to an embodiment of the invention.

FIG. 43 depicts a third cross-sectional view corresponding to the line D in FIG. 16 following wafer flipping, semiconductor substrate removal, backside ILD layer formation and planarization, according to an embodiment of the invention.

FIG. 44 depicts a fourth cross-sectional view corresponding to the line Y in FIG. 16 following wafer flipping, semiconductor substrate removal, backside ILD layer formation and planarization, according to an embodiment of the invention.

FIG. 45 depicts a first cross-sectional view corresponding to the line X in FIG. 16 following sacrificial placeholder layer removal, backside contact formation and planarization, according to an embodiment of the invention.

FIG. 46 depicts a second cross-sectional view corresponding to the line S in FIG. 16 following sacrificial placeholder layer removal, backside contact formation and planarization, according to an embodiment of the invention.

FIG. 47 depicts a third cross-sectional view corresponding to the line D in FIG. 16 following sacrificial placeholder layer removal, backside contact formation and planarization, according to an embodiment of the invention.

FIG. 48 depicts a fourth cross-sectional view corresponding to the line Y in FIG. 16 following sacrificial placeholder layer removal, backside contact formation and planarization, according to an embodiment of the invention.

FIGS. 49-56 depict cross-sectional views of drain regions including different frontside drain contact configurations and/or different epitaxial region contact structure configurations, according to embodiments of the invention.

FIGS. 57-60 depict cross-sectional views of source regions including a frontside source contact configuration and different backside epitaxial region contact structures configuration, according to embodiments of the invention.

FIGS. 61-63 depict cross-sectional views of drain regions including different epitaxial region contact structure configurations for a non-stacked FET, according to embodiments of the invention.

FIGS. 64-68 depict cross-sectional views of source regions including different epitaxial region contact structure configurations for a non-stacked FET, according to embodiments of the invention.

### DETAILED DESCRIPTION

Illustrative embodiments of the invention may be described herein in the context of illustrative methods for forming epitaxial region contact structures for FETs, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A field-effect transistor (FET) is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7 nm and beyond. A general process flow for formation of a nanosheet stack involves selectively removing sacrificial layers, which may be formed of silicon germanium (SiGe) between sheets of channel material, which may be formed of silicon (Si).

For continued scaling (e.g., to 2.5 nm and beyond), next-generation stacked FET devices may be used. Next-generation stacked FET devices provide a complex gate-all-around (GAA) structure. Conventional GAA FETs, such as nanosheet FETs, may stack multiple p-type nanowires or nanosheets on top of each other in one device, and may stack multiple n-type nanowires or nanosheets on top of each other in another device. Next-generation stacked FET structures provide improved track height scaling, leading to structural gains (e.g., such as 30-40% structural gains for different types of devices, such as logic devices, static random-access memory (SRAM) devices, etc.). In next-generation stacked FET structures, n-type and p-type nanowires or nanosheets are stacked on each other, eliminating n-to-p separation bottlenecks and reducing the device area footprint. There is, however, a continued desire for further scaling and reducing the size of FETs.

As discussed above, various techniques may be used to reduce the size of FETs, including through the use of fin-shaped channels in FinFET devices, through the use of stacked nanosheet channels formed over a semiconductor substrate, and next-generation stacked FET devices.

Although embodiments of the present invention are discussed in connection with nanosheet stacks, the embodiments of the present invention are not necessarily limited thereto, and may similarly apply to nanowire stacks.

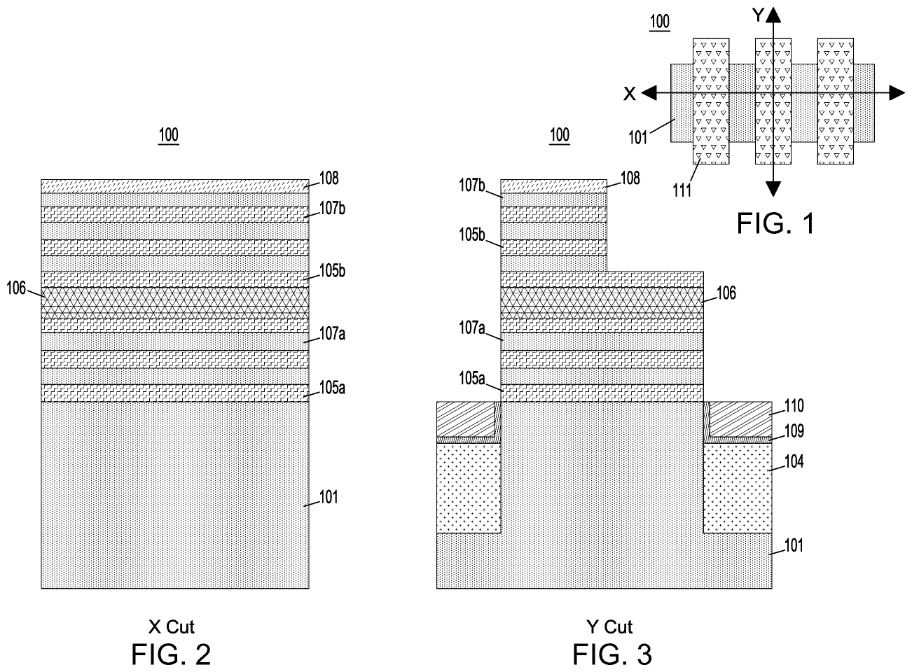

FIG. 1 depicts a top view of a semiconductor structure with lines X and Y on which the cross-sectional views of FIGS. 2-11 are based. FIG. 1 illustrates dummy gate portions 111 and portions of a semiconductor substrate 101. Referring to FIGS. 2 and 3, a semiconductor substrate 101 comprises semiconductor material including, but not limited to, silicon, III-V, II-V compound semiconductor materials or other like semiconductor materials. In addition, multiple layers of the semiconductor materials can be used as the semiconductor material of the semiconductor substrate 101.

First sacrificial layers 105a and first channel layers 107a corresponding to lower transistors of stacked transistors are epitaxially grown in an alternating and stacked configuration on the semiconductor substrate 101. A middle sacrificial layer 106 is epitaxially grown on an uppermost first sacrificial layer 105a of the lower transistors. Second sacrificial layers 105b and second channel layers 107b corresponding to upper transistors of stacked transistors are epitaxially grown in an alternating and stacked configuration on the middle sacrificial layer 106. In either case, a first one of the first sacrificial layers 105a is followed by a first channel layer 107a on the first one of the first sacrificial layers 105a, which is followed by a second one of the first sacrificial layers 105a on the first channel layer 107a, and so on. Similarly, a first one of the second sacrificial layers 105b is followed by a second channel layer 107b on the first one of the second sacrificial layers 105b, which is followed by a second one of the second sacrificial layers 105b on the second channel layer 107b, and so on. As can be understood, the first and second sacrificial layers 105a and 105b and first and second channel layers 107b are epitaxially grown from their corresponding underlying semiconductor layers.

In an illustrative embodiment, the first and second sacrificial layers 105a and 105b and middle sacrificial layer 106 comprise silicon germanium (SiGe) and the first and second channel layers 107a and 107b comprise silicon. In illustrative embodiments, the first and second sacrificial layers 105a and 105b comprise a germanium concentration of about 30% (e.g., SiGe30) and the middle sacrificial layer 106 comprises a germanium concentration of about 60% (e.g., SiGe60), but the embodiments are not necessarily limited to SiGe30 and SiGe60 for the first and second sacrificial layers 105a and 105b and middle sacrificial layer 106.

The embodiments are not necessarily limited to the shown number of first and second sacrificial layers 105a and 105b and first and second channel layers 107a and 107b, and there may be more or less layers in the same alternating configuration depending on design constraints. The first and second sacrificial layers 105a and 105b, as described further herein, are eventually removed and replaced by gate structures.

Although SiGe is described as a sacrificial material for first and second sacrificial layers 105a and 105b, other materials can be used as long as the first and second sacrificial layers 105a and 105b have the property of being able to be removed selectively compared to the material of the first and second channel layers 107a and 107b.

The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

The epitaxial deposition process may employ the deposition chamber of a chemical vapor deposition type apparatus, such as a metal-organic chemical vapor deposition (MOCVD), rapid thermal chemical vapor deposition (RTCVD), ultra-high vacuum chemical vapor deposition (UHVCVD), or a low-pressure chemical vapor deposition (LPCVD) apparatus. A number of different sources may be used for the epitaxial deposition of the in situ doped semiconductor material. In some embodiments, the gas source for the deposition of an epitaxially formed semiconductor material may include silicon (Si) deposited from silane, disilane, trisilane, tetrasilane, hexachlorodisilane, tetrachlorosilane, dichlorosilane, trichlorosilane, and combinations thereof. In other examples, when the semiconductor material includes germanium, a germanium gas source may be selected from the group consisting of germane, digermane, halogermane, dichlorogermane, trichlorogermane, tetrachlorogermane and combinations thereof. The temperature for epitaxial deposition typically ranges from 450° C. to 900° C. Although higher temperature typically results in faster deposition, the faster deposition may result in crystal defects and film cracking.

In a non-limiting illustrative embodiment, a height of the first and second sacrificial layers 105a and 105b can be in the range of about 6 nm to about 15 nm depending on the application of the device. Also, in a non-limiting illustrative embodiment, a height of the first and second channel layers 107a and 107b can be in the range of about 6 nm to about 15 nm depending on the desired process and application. In accordance with an embodiment of the present invention, each of the first and second channel layers 107a and 107b has the same or substantially the same composition and size as each other, and each of the first and second sacrificial layers 105a and 105b has the same or substantially the same composition and size as each other.

As used herein, “frontside or “first side” refers to a side on top of the semiconductor substrate 101 and/or in front of, on top of or in an upward direction from the stacked nanosheet/gate and channel layers of the transistors in the orientation shown in the cross-sectional figures. As used herein, “backside” or “second side” refers to a side below the semiconductor substrate 101 and/or behind, under, below or in a downward direction from the stacked nanosheet/gate and channel layers of the transistors in the orientation shown in the cross-sectional figures (e.g., opposite the “frontside”).

Exposed portions of the nanosheet stacks comprising the first and second sacrificial layers 105a and 105b and middle sacrificial layer 106 and first and second channel layers 107a and 107b not covered by a dielectric mask layer 108 are removed or recessed, and following the removal, exposed portions of the semiconductor substrate 101 are recessed. Isolation regions 104 (e.g., shallow trench isolation (STI)) regions are formed between the remaining nanosheet stacks in the recessed portions of the semiconductor substrate 101. Isolation regions 104 comprising dielectric material fill in part of the recessed portions of the semiconductor substrate 101. The dielectric material of the isolation regions and dielectric mask layer 108 may comprise, for example, SiO₂, silicon nitride (Si₃N₄), silicon oxynitride (SiON), silicon-carbon-nitride (SiCN), boron nitride (BN), silicon boron nitride (SiBN), silicoboron carbonitride (SiBCN), silicon oxycarbonitride (SiOCN) and combinations thereof, and is deposited using deposition techniques such as, for example, chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD). In addition, a dual dielectric portion including a nitride liner 109 and an oxide layer 110 is formed on the isolation regions 104 in remaining parts of the recessed portions of the semiconductor substrate 101. As can be seen in FIG. 3, a width (left-right dimension) of the first sacrificial layers 105a, first channel layers 107a and middle sacrificial layer 106 is larger than a width of the second sacrificial layers 105b and second channel layers 107b.

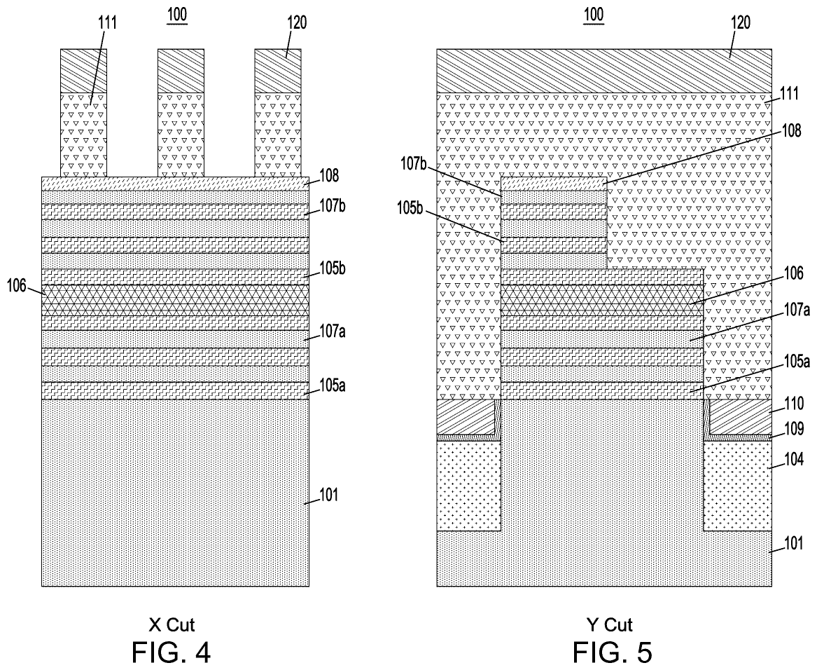

Referring to FIGS. 4 and 5, dummy gate portions 111 are formed on the uppermost second channel layers 107a and around the stacked nanosheet configurations of the first and second sacrificial layers 105a and 105b, middle sacrificial layer 106 and first and second channel layers 107a and 107b. The dummy gate portions 111 include, but are not necessarily limited to, an amorphous silicon (a-Si) layer. The dummy gate portions 111 are deposited using deposition techniques such as, for example, CVD, PECVD, RFCVD, PVD, ALD, MBD, PLD, LSMCD, sputtering and/or plating, followed by a planarization process, such as, chemical mechanical planarization (CMP), and lithography and etching steps to remove excess dummy gate material, and pattern the deposited layer. Hardmask layers 120 are formed on the dummy gate portions 111. The hardmask layers 120 comprise, for example, a nitride such as Si₃N₄ or other nitride material.

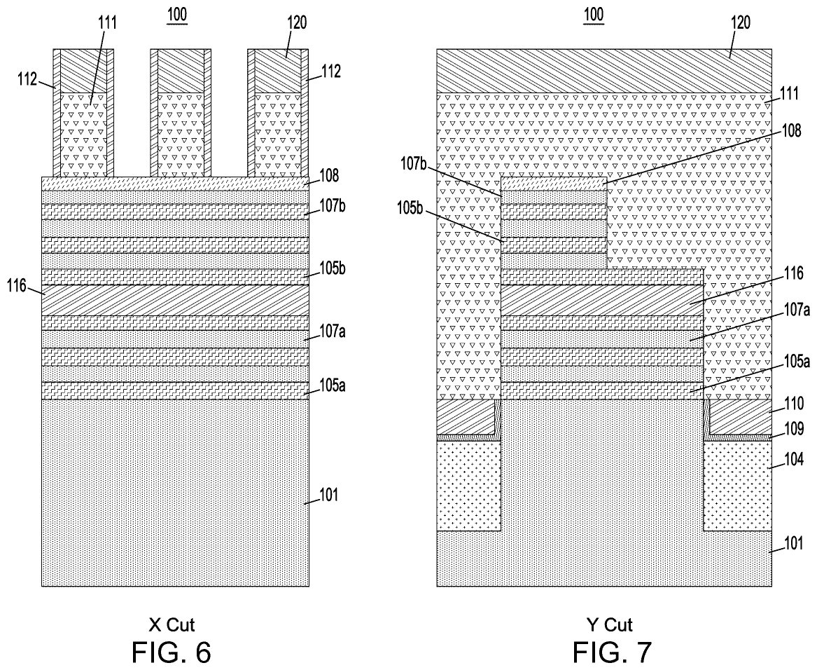

Referring to FIGS. 6 and 7, a remaining portion of the middle sacrificial layer 106 are removed using, for example, a plasma dry etch that contains HCl gas chemistry to selectively etch the portion of the middle sacrificial layer 106 with respect to the portions of the semiconductor substrate 101, the first and second sacrificial layers 105a and 105b and the first and second channel layers 107a and 107b. The selective etching removes the remaining portion of the middle sacrificial layer 106 to form vacant areas where an MDI layer 116 will be formed.

Following the removal of the remaining portions of the middle sacrificial layer 106, dielectric material is deposited in place of the remaining portion of the middle sacrificial layer 106 using deposition techniques such as, for example, CVD, PECVD, RFCVD, PVD, ALD, MBD, PLD, and/or LSMCD, followed by an etch back to form the MDI layer 116. The MDI layer 116 may comprise, for example, silicon oxide (SiOₓ) (where x is for example, 2, 1.99 or 2.01), silicon oxycarbide (SiOC), Si₃N₄, SiON, SiCN, BN, SiBCN, SiOCN or some other dielectric.

Gate spacers 112 are formed on sides of the hardmask layers 120 and dummy gate portions 111 by one or more of the deposition techniques noted in connection with deposition of the dummy gate material. The spacer material can comprise for example, one or more dielectrics, including, but not necessarily limited to, Si₃N₄, SiON, SiOC, SiCN, BN, SiBN, SiBCN, SiOCN, SiOₓ, and combinations thereof. According to an embodiment, the hardmask layers 120 and gate spacers 112 can be the same material or different materials. The gate spacers 112 can be formed by any suitable technique such as deposition followed by directional etching. Deposition may include, but is not limited to, ALD or CVD. Directional etching may include but is not limited to, reactive ion etching (RIE).

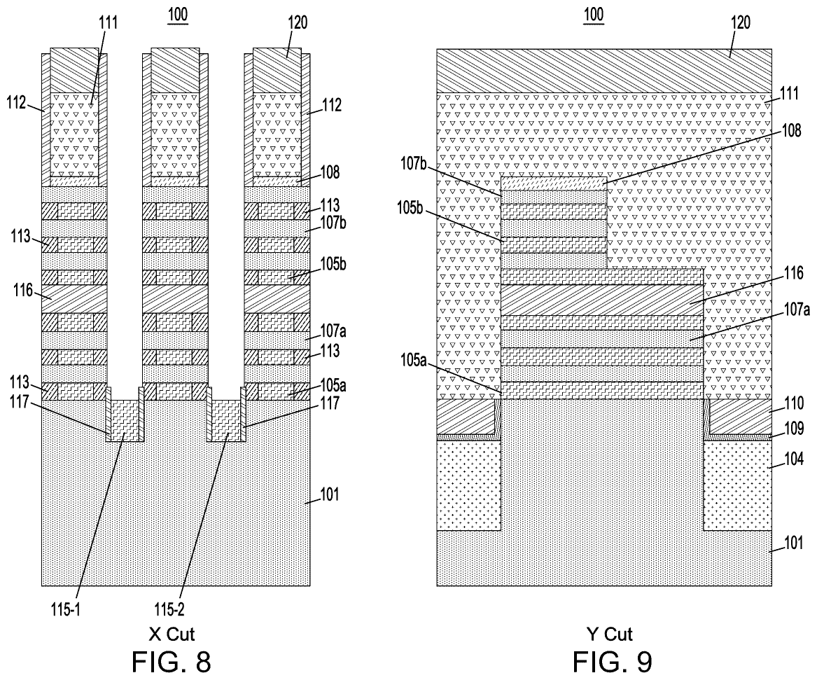

Referring to FIGS. 8 and 9, exposed portions of the stacked first and second sacrificial layers 105a and 105b, first and second channel layers 107a and 107b and MDI layer 116, which are not under the hardmask layers 120, gate spacers 112 and dummy gate portions 111, arc removed using, for example, an etching process, such as RIE, where the hardmask layers 120, gate spacers 112 and dummy gate portions 111 are used as a mask. The portions of the stacked structures of the first and second sacrificial layers 105a and 105b, first and second channel layers 107a and 107b and MDI layer 116 under the hardmask layers 120, gate spacers 112 and under the dummy gate portions 111 remain after the etching process, and portions of the first and second sacrificial layers 105a and 105b, first and second channel layers 107a and 107b and MDI layer 116 in areas that correspond to where source/drain regions will be formed are removed.

Due to, for example, germanium in the first and second sacrificial layers 105a and 105b, lateral etching of the first and second sacrificial layers 105a and 105b can be performed selective to the first and second channel layers 107a and 107b, such that the side portions of the first and second sacrificial layers 105a and 105b can be removed to create vacant areas to be filled in by inner spacers 113. The material of the inner spacers 113 can comprise, but is not necessarily limited to, a nitride, such as, Si₃N₄, SiON, SiCN, BN, SiBN, SiBCN or SiOCN. Gate spacers 112 are positioned on the nanosheet stacks on opposite lateral sides of the dummy gate portions 111. In an illustrative embodiment, the gate spacers 112 are formed from the same or similar material to that of the inner spacers 113. Like the gate spacers 112, the inner spacers 113 can be formed by any suitable techniques such as deposition followed by isotropic etching.

Exposed portions of the semiconductor substrate 103, which are not under the hardmask layers 120, gate spacers 112 and dummy gate portions 111, are removed, such that portions of the semiconductor substrate 101 are recessed to create openings (also referred to herein as “trenches”) in the semiconductor substrate 101. The semiconductor substrate 101 can be etched using, for example, a dry etch process. The exposed portions of the semiconductor substrate 101 are recessed below the bottom surfaces of the lowermost first sacrificial layers 105a.

Sacrificial placeholder layers 115-1 and 115-2 (collectively “sacrificial placeholder layers 115”) are formed in the trenches. The dielectric spacer layers 117 are formed on sides of the sacrificial placeholder layers 115. The sacrificial placeholder layers 115 include, for example, SiGe, III-V semiconductor material or other semiconductor material. The sacrificial placeholder layers 115 are deposited in the trenches using deposition techniques such as, for example, epitaxial growth, CVD, PECVD, RFCVD, PVD, ALD, MBD, PLD, and/or LSMCD.

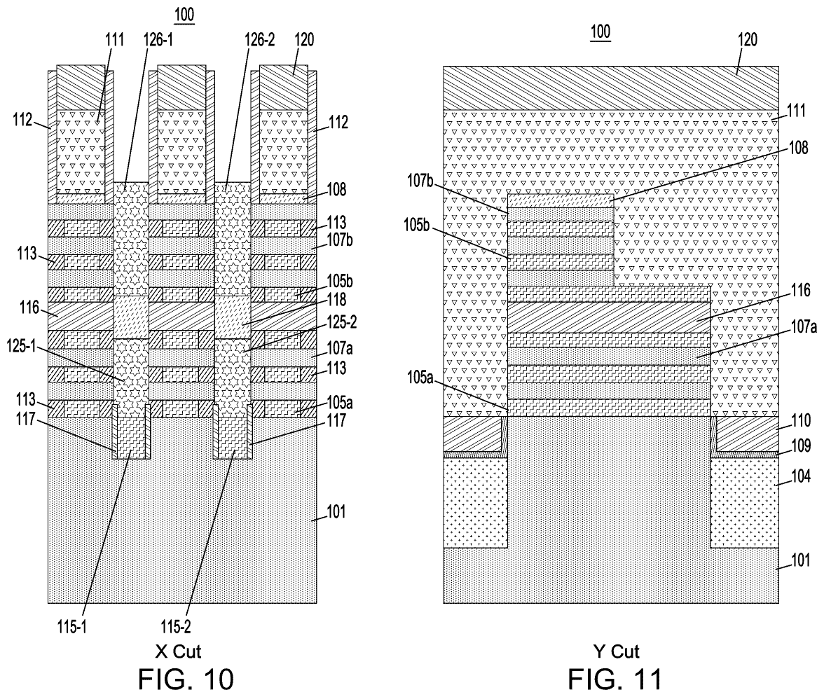

Referring to FIGS. 10 and 11, bottom source/drain regions 125-1 and 125-2 (collectively “bottom source/drain regions 125”) and top source/drain regions 126-1 and 126-2 (collectively “top source/drain regions 126”) are epitaxially grown between the nanosheet stacks. As explained in more detail herein, in illustrative embodiments, the bottom source/drain region 125-1 and the top source/drain region 126-1 are each source regions of a transistor, and the bottom source/drain region 125-2 and the top source/drain region 126-2 are each drain regions. The bottom source/drain regions 125 correspond to a lower transistor and the top source/drain regions 126 correspond to an upper transistor of the stacked structure of respective lower and upper transistors. The bottom and top source/drain regions 125 and 126 comprise epitaxial layers grown from sides of respective corresponding first and second channel layers 107a and 107b and/or from top surfaces of the sacrificial placeholder layers 115. As can be seen, the bottom source/drain regions 125 are formed on and contact corresponding ones of underlying sacrificial placeholder layers 115.

Side surfaces of respective ones of the corresponding first and second channel layers 107a and 107b contact a side surface of at least one adjacent top or bottom source/drain region 125 or 126. A first inter-level dielectric layer 118 is formed between the top and bottom source/drain regions 126 and 125. The first inter-level dielectric (ILD) layer 118 fills in portions on and around the bottom source/drain regions 125. The first ILD layer 118 is deposited using deposition techniques such as, for example, CVD, PECVD, RFCVD, PVD, ALD, MBD, PLD, and/or LSMCD. The first ILD layer 118 may comprise, for example, SiOₓ, SiOC, SiOCN or some other dielectric.

According to a non-limiting embodiment of the present invention, the conditions of the epitaxial growth process for the bottom and top source/drain regions 125 and 126 are, for example, RTCVD epitaxial growth using SiH₄, SiH₂Cl₂, GcH₄, CH₃SiH₃, B₂H₆, PF₃, and/or H₂ gases with temperature and pressure ranges of about 450° C. to about 800° C., and about 5 Torr-about 300 Torr. In the case of n-type FETS (nFETs), the bottom or top source/drain regions 142 and 143 can comprise silicon doped with n-type dopants including, for example, phosphorus (P), arsenic (As) and antimony (Sb). In the case of p-type FETS (pFETs), the bottom or top source/drain regions 142 and 143 can comprise silicon doped with n-type dopants including, for example, boron (B), boron fluoride (BF₂), gallium (Ga), indium (In), and thallium (Tl).

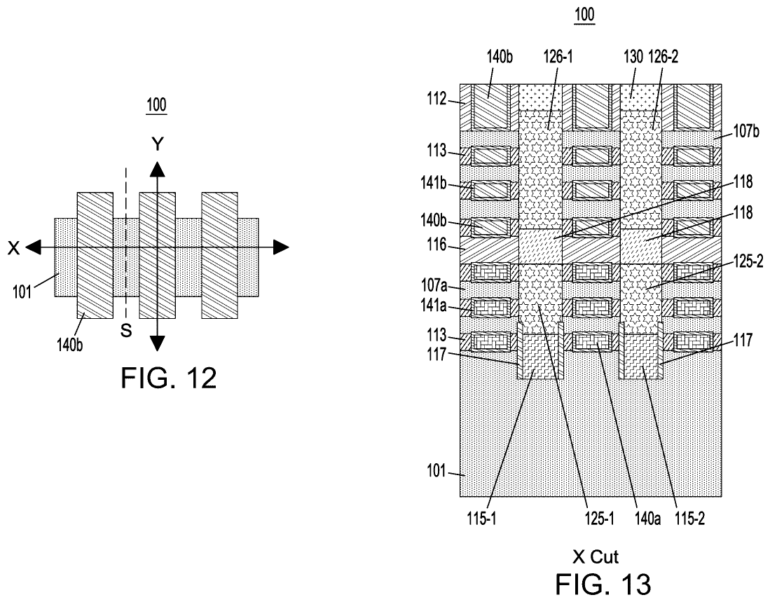

Referring to FIGS. 12-15, a second ILD layer 130 is deposited to fill in portions on and around the top source/drain regions 126. The second ILD layer 130 is deposited using deposition techniques such as, for example, CVD, PECVD, RFCVD, PVD, ALD, MBD, PLD, and/or LSMCD, followed by a planarization process, such as, CMP to remove excess portions of the second ILD layer 130 deposited on top of the hardmask layers 120 and gate spacers 112, and to remove the hardmask layers 120 and portions of the gate spacers 112 to expose the dummy gate portions 111. The second ILD layer 130 may comprise, for example, SiOₓ, SiOC, SiOCN or some other dielectric.

Dummy gate portions 111 are selectively removed to create vacant areas where gate structures will be formed in place of the dummy gate portions 111. The selective removal can be performed using, for example, hot ammonia to remove a-Si. In addition, the first and second sacrificial layers 105a and 105b are selectively removed to create vacant areas where gate structures will be formed in place of the first and second sacrificial layers 105a and 105b. The first and second sacrificial layers 105a and 105b are selectively removed with respect to the first and second channel layers 107a and 107b. The selective removal can be performed using, for example, a dry HCl etch.

Following removal of the dummy gate portions 111 and first and second sacrificial layers 105a and 105b, the first and second channel layers 107a and 107b are suspended, and first and second gate structures 140a and 140b and first and second gate dielectric layers 141a and 141b are formed in the vacant portions left by removal of the dummy gate portions 111, and the first and second sacrificial layers 105a and 105b. In illustrative embodiments, respective ones of the first and second gate dielectric layers 141a and 141b includes a gate dielectric layer such as, for example, a high-K dielectric layer including, but not necessarily limited to, HfO₂ (hafnium oxide), ZrO₂ (zirconium dioxide), hafnium zirconium oxide, Al₂O₃ (aluminum oxide), and Ta₂O₅ (tantalum oxide). Examples of high-k materials also include, but are not limited to, metal oxides such as hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. According to an embodiment, the first and second gate structures 140a and 140b each include a metal gate portion including a work-function metal (WFM) layer, including but not necessarily limited to, for a pFET, titanium nitride (TiN), tantalum nitride (TaN) or ruthenium (Ru), and for an nFET, TiN, titanium aluminum nitride (TiAlN), titanium aluminum carbon nitride (TiAlCN), titanium aluminum carbide (TiAlC), tantalum aluminum carbide (TaAlC), tantalum aluminum carbon nitride (TaAlCN) or lanthanum (La) doped TiN, TaN, which can be deposited on the gate dielectric layer. The first and second gate structures 140a and 140b can also each further include a gate metal layer including, but not necessarily limited to, metals, such as, for example, tungsten, cobalt, zirconium, tantalum, titanium, aluminum, ruthenium, copper, metal carbides, metal nitrides, transition metal aluminides, tantalum carbide, titanium carbide, tantalum magnesium carbide, or combinations thereof deposited on the WFM layer and the gate dielectric layer. In an illustrative embodiment, the lower transistor comprises a pFET, while the upper transistor comprises an nFET or vice versa.

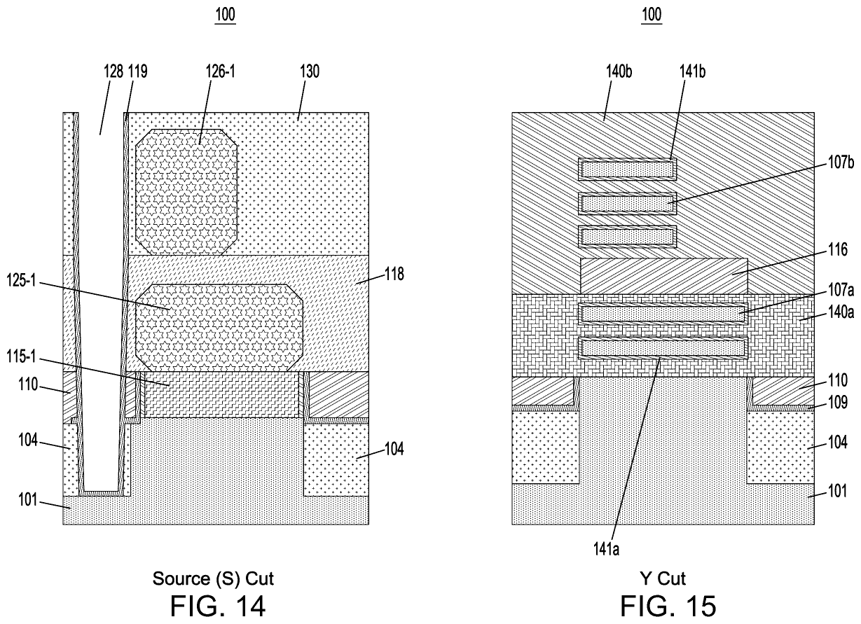

As can be seen in FIG. 14, patterning for a via is performed. In more detail, the first and second ILD layers 118 and 130, and underlying portions of the dual dielectric layer and an isolation region 104 are etched to create an opening 128 (trench) through the first and second ILD layers 118 and 130, and underlying portions of the dual dielectric layer and an isolation region 104. In an illustrative embodiment, the opening 128 is lined on side and bottom portions with a via liner layer 119. The via liner layer 119 may include, for example, titanium and/or titanium nitride. FIG. 14 further illustrates that the upper and lower source/drain regions 126-1 and 125-1, which as noted herein above, are source regions in illustrative embodiments, have different widths (left-right/horizontal dimension in FIG. 14). As can be seen in FIG. 14, the bottom source/drain region 125-1 is wider than the top source/drain region 126-1. Additionally, as can be seen in FIGS. 13 and 14, the upper and lower source/drain regions 126-1 and 125-1 have different heights (up-down/vertical dimension) from each other. The bottom source/drain region 125-1 is shorter than the top source/drain region 126-1.

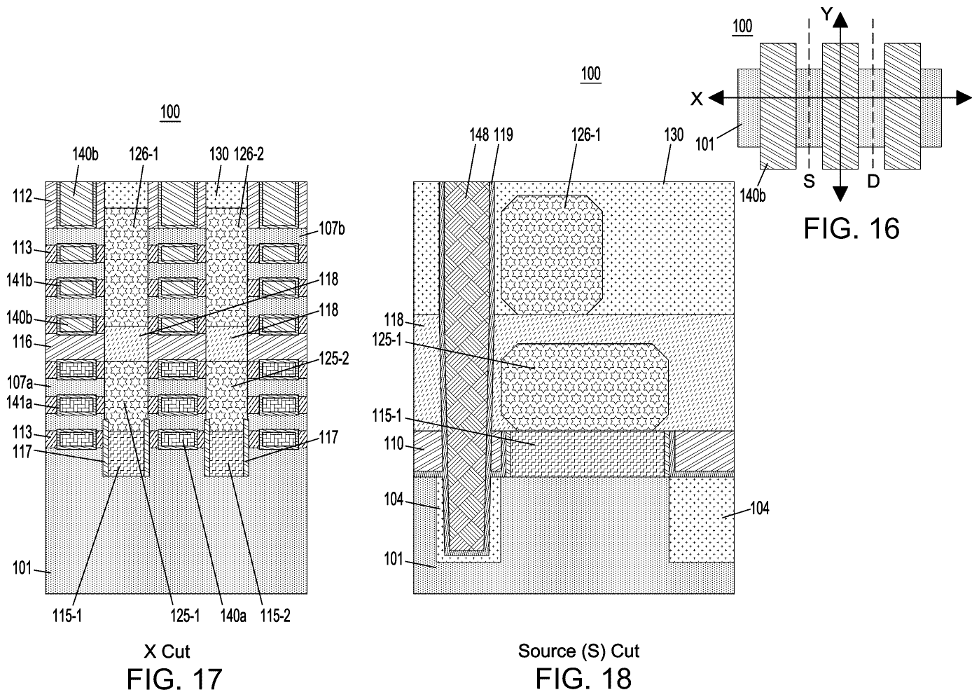

Referring to FIGS. 16-19, a via conductive layer 148 is deposited to fill in a remaining portion of the opening 128. In illustrative embodiments, the via conductive layer 148 comprises, for example, a conductive metal fill layer, such as W, Mo, Co, Ru, etc., and can be deposited using, for example, a deposition technique such as CVD, PECVD, RFCVD, PVD, ALD, MBD, PLD, LSMCD, sputtering and/or plating, followed by a planarization process such as, CMP to remove excess portions of the metal layers from on top of the second ILD layer 130. The liner layer 119 is optional and may be omitted.

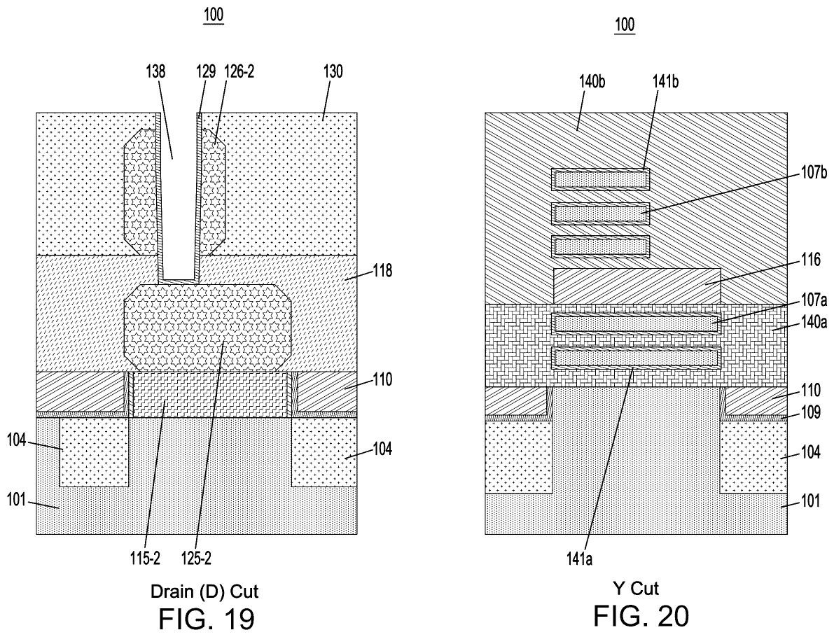

FIG. 19 illustrates that, like the upper and lower source/drain regions 126-1 and 125-1, the upper and lower source/drain regions 126-2 and 125-2, which as noted herein above, are drain regions in illustrative embodiments, have different widths (left-right/horizontal dimension in FIG. 19). As can be seen in FIG. 19, the bottom source/drain region 125-2 is wider than the top source/drain region 126-2. Additionally, as can be seen in FIGS. 17 and 19, the upper and lower source/drain regions 126-2 and 125-2 have different heights (up-down/vertical dimension) from each other. The bottom source/drain region 125-2 is shorter than the top source/drain region 126-2.

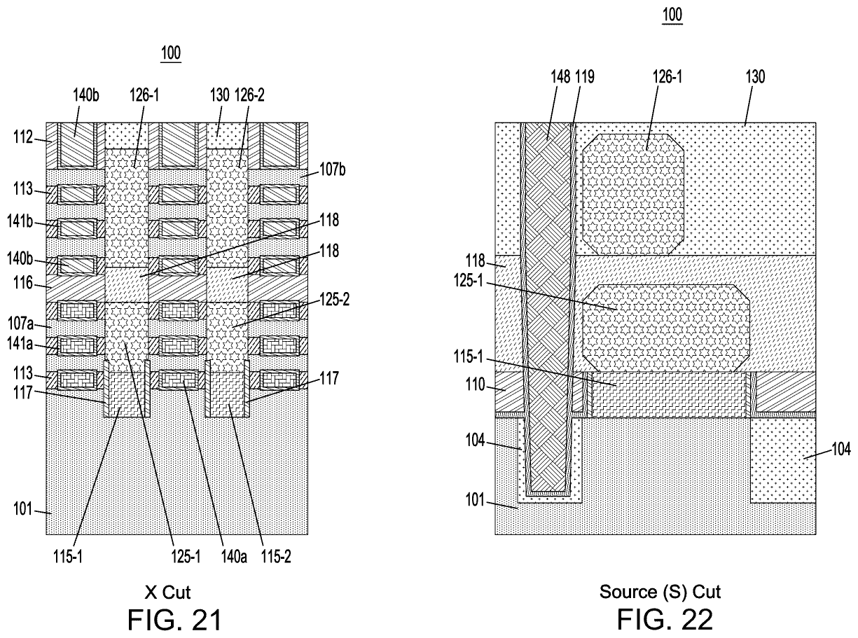

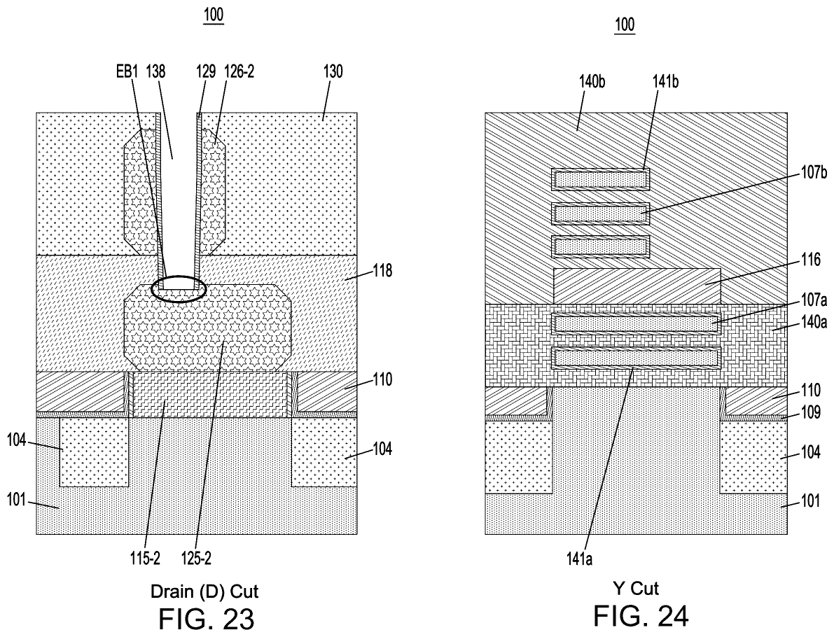

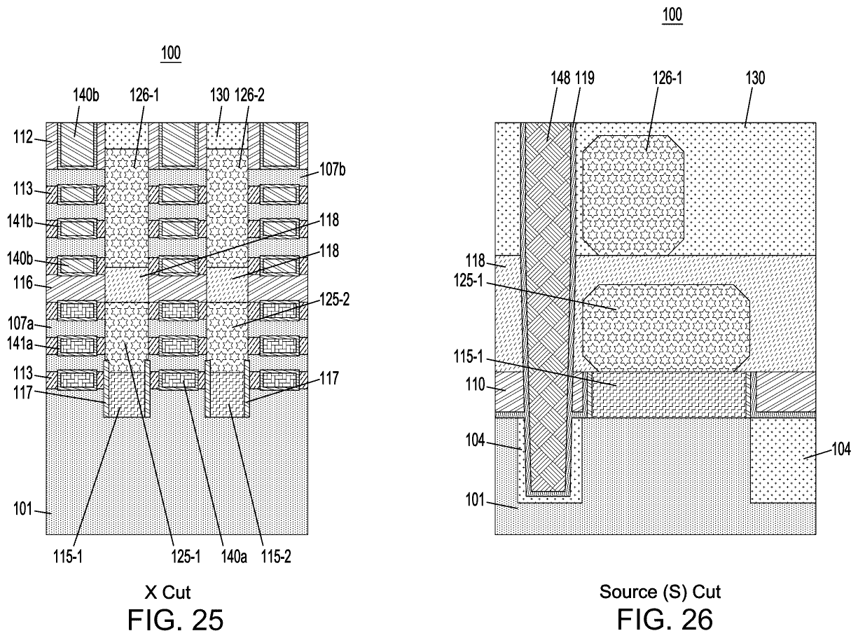

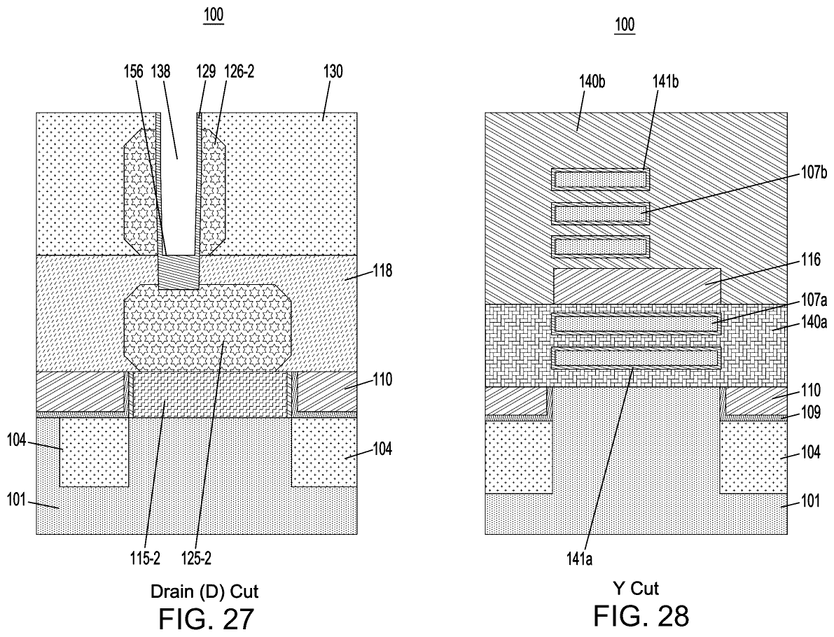

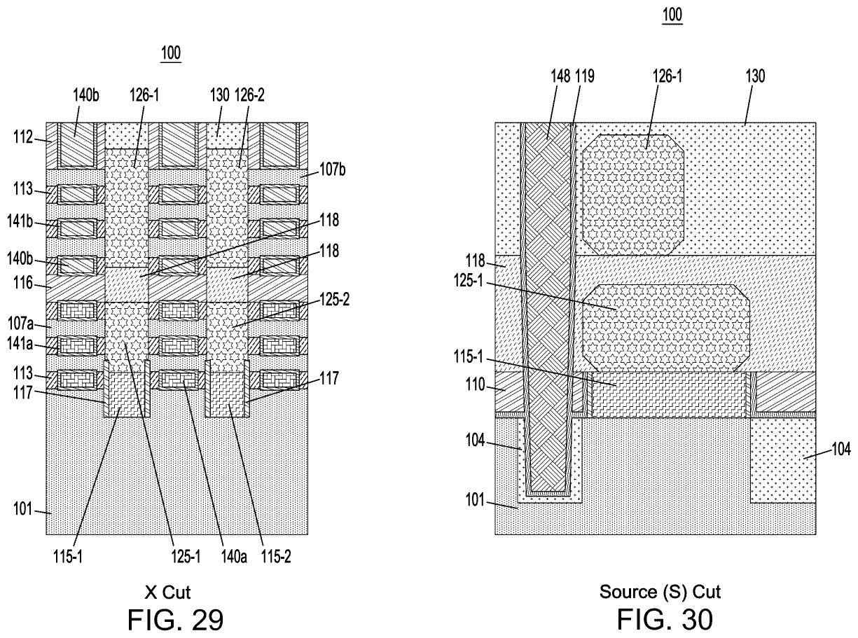

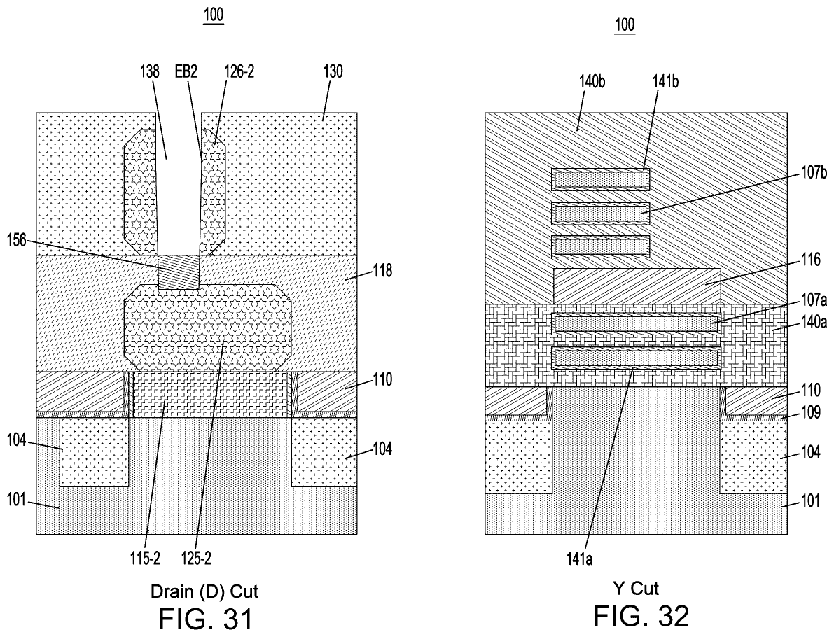

As can be seen in FIG. 19, patterning for an epitaxial region contact structure is performed. In more detail, the second ILD layer 130, the top source/drain region 126-2 and an underlying portion of the first ILD layer 118 are etched to create an opening 138 (trench) through the second ILD layer 130, the top source/drain region 126-2 and a portion of the first ILD layer 118 to expose a top surface of the bottom source/drain region 125-2. In an illustrative embodiment, the opening 138 is lined on side and bottom portions with a sacrificial spacer layer 129 that protects the top source/drain region 126-2 during processing. The sacrificial spacer layer 129 may include dielectric materials, for example, silicon nitride (Si₃N₄), aluminum oxide (Al₂O₃), aluminum nitride (AlN), or any suitable thin nitride or oxide layer. Referring to the circled portion EB1 in FIG. 23, an etch-back process is performed to remove a bottom portion of the sacrificial spacer layer 129 to expose the top surface of the bottom source/drain region 125-2. Then, referring to FIG. 27, a sacrificial epitaxial blocking layer 156 is formed at a lower portion of the opening 138 in the first ILD layer 118 below the top source/drain region 126-2. The sacrificial epitaxial blocking layer 156 includes a different concentration of SiGe than either of the top source/drain region 126-2 or the bottom source/drain region 125-2 so that a selective etch process allows for removal of the sacrificial epitaxial blocking layer 156. In some embodiments, the sacrificial epitaxial blocking layer 156 may also be formed by depositing a dielectric material such as, for example, aluminum oxide Al₂O₃, aluminum nitride (AlN), followed by an etch back process using, for example, a dry etching process using a RIE or ion beam etch (IBE) process, a wet chemical etch process, or a combination of etching processes. Referring to FIG. 31, in another etch-back process (EB2), the exposed portions of the sacrificial spacer layer 129 on the sides of the opening 138 are removed to expose inner side portions of the top source/drain region 126-2. The etch-back processes EB1 and EB2 include, for example, a dry etching process using a RIE or ion beam etch (IBE) process, a wet chemical etch process or a combination of etching processes. FIGS. 21, 22 and 24, FIGS. 25, 26 and 28, and FIGS. 29, 30 and 32 are the same as FIGS. 17, 18 and 20 and are shown for easy reference.

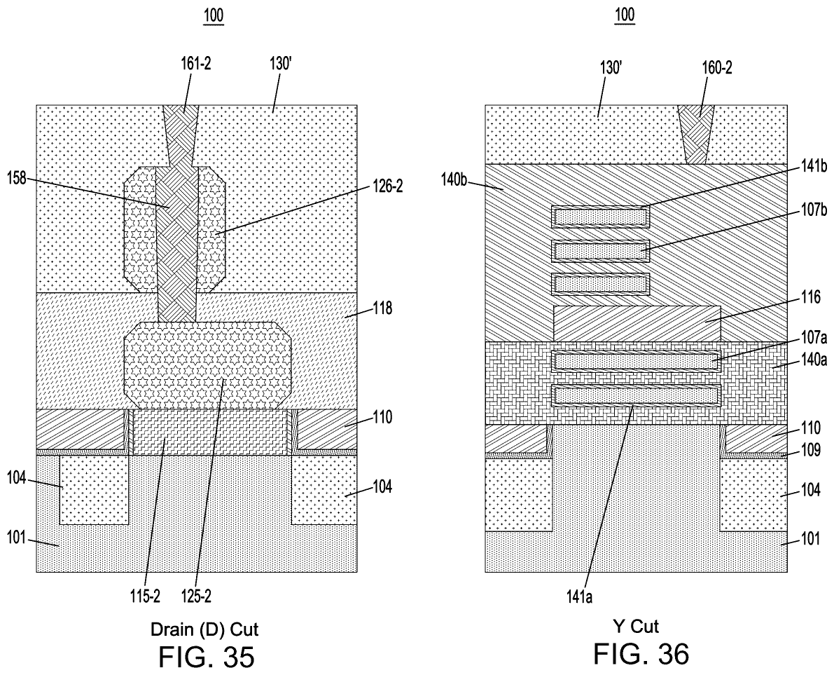

Referring to FIG. 35, the remaining portion of the sacrificial epitaxial blocking layer 156 is removed using, for example, a dry etching process using a RIE or ion beam etch (IBE) process, a wet chemical etch process or a combination of etching processes, and one or more conductive layers are deposited to fill in the opening 138 to form drain epitaxial region contact structure 158. In illustrative embodiments, the drain epitaxial region contact structure 158 comprises, for example, a conductive metal fill layer, such as W, Mo, Co, Ru, etc., and can be deposited using, for example, a deposition technique such as CVD, PECVD, RFCVD, PVD, ALD, MBD, PLD, LSMCD, sputtering and/or plating, followed by a planarization process such as, CMP to remove excess portions of the metal layers from on top of the second ILD layer 130. In some embodiments, a liner layer (not shown) similar to the via liner layer 119 (e.g., titanium and/or titanium nitride) is deposited to line the sides and bottom of the opening 138 prior to depositing the conductive metal fill layer. As can be seen in FIG. 35, the drain epitaxial region contact structure 158 extends through the top source/drain region 126-2 and a through a portion of the first ILD layer 118 to land on and contact a top surface of the bottom source/drain region 125-2. The drain epitaxial region contact structure 158 contacts the inner side portions of the top source/drain region 126-2. By virtue of the contact with the inner side portions of the top source/drain region 126-2 and the top surface of the bottom source/drain region 125-2, the drain epitaxial region contact structure 158 electrically connects the top source/drain region 126-2 to the bottom source/drain region 125-2.

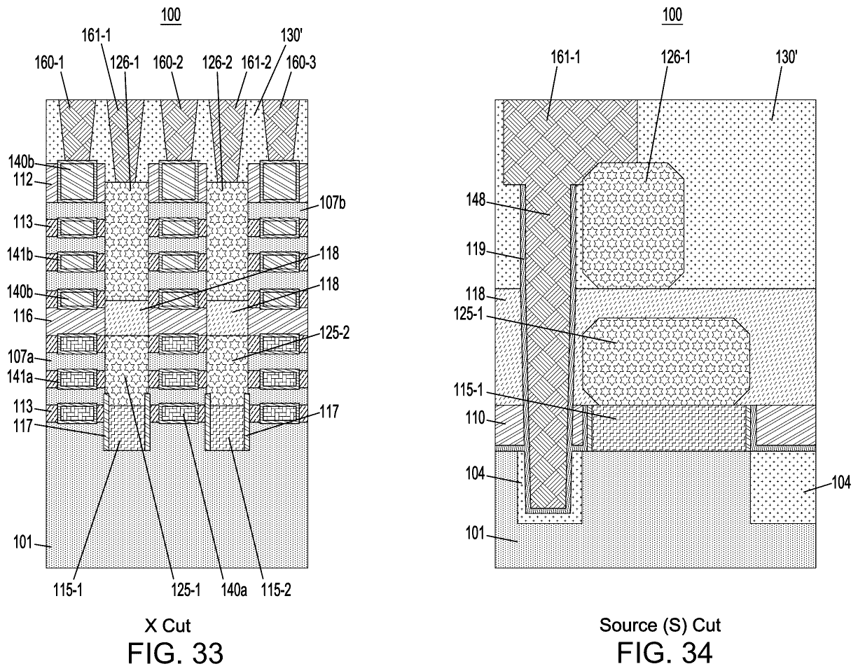

Referring to FIGS. 33-36, a third ILD layer 130′ is deposited. The third ILD layer 130′ may include the same materials as or similar materials to those of the first and second ILD layers 118 and 130. First, second and third frontside gate contacts 160-1, 160-2 and 160-3 (collectively, “frontside gate contacts 160”), and first and second frontside source/drain contacts 161-1 and 161-2 (collectively “frontside source/drain contacts 161”) are formed in the second and third ILD layers 130 and 130′.

In forming the frontside gate contacts 160 and the frontside source/drain contacts 161, openings are formed through portions of the second and third ILD layers 130 and 130. For the frontside gate contacts 160, the openings expose portions of the second gate structures 140b on which the frontside gate contacts 160 are to be formed, and for the frontside source/drain contacts 161, the openings expose the top source/drain regions 126 and/or other contacts structures on which the frontside source/drain contacts 161 are to be formed. For example, the first frontside source/drain contact 161-1 is formed on and contacts the via conductive layer 148 and the top source/drain region 126-1, and the second frontside source/drain contact 161-2 contacts the drain epitaxial region contact structure 158, and may also directly contact part of the top source/drain region 126-2. According to an embodiment, masks are formed on parts of the third ILD layer 130, and exposed portions of the second and third ILD layers 130 and 130 corresponding to where the openings are to be formed are removed using, for example, a dry etching process using a RIE or ion beam etch (IBE) process, a wet chemical etch process or a combination of these etching processes. A dry etch may be performed using a plasma. Such wet or dry etch processes include, for example, IBE by Ar/CHF3 based chemistry.

Metal layers comprising the same or similar materials as those used for the drain epitaxial region contact structure 158 and the via conductive layer 148 are deposited in the openings to form the frontside gate contacts 160 and the frontside source/drain contacts 161. The metal layers can be deposited using, for example, the same or similar deposition techniques as used for the drain epitaxial region contact structure 158 and the via conductive layer 148, followed by a planarization process such as, CMP to remove excess portions of the metal layers from on top of the third ILD layer 130′. In some embodiments, a liner layer (not shown) similar to the via liner layer 119 (e.g., titanium and/or titanium nitride) is deposited to line the sides and bottom of the openings prior to depositing the metal layers for the frontside gate contacts 160 and the frontside source/drain contacts 161.

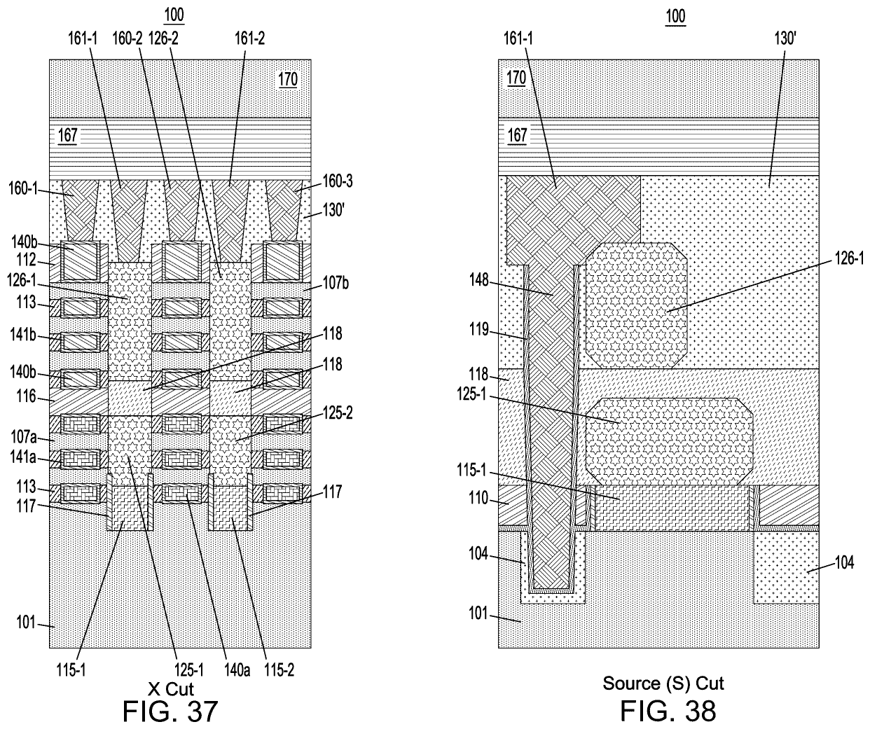

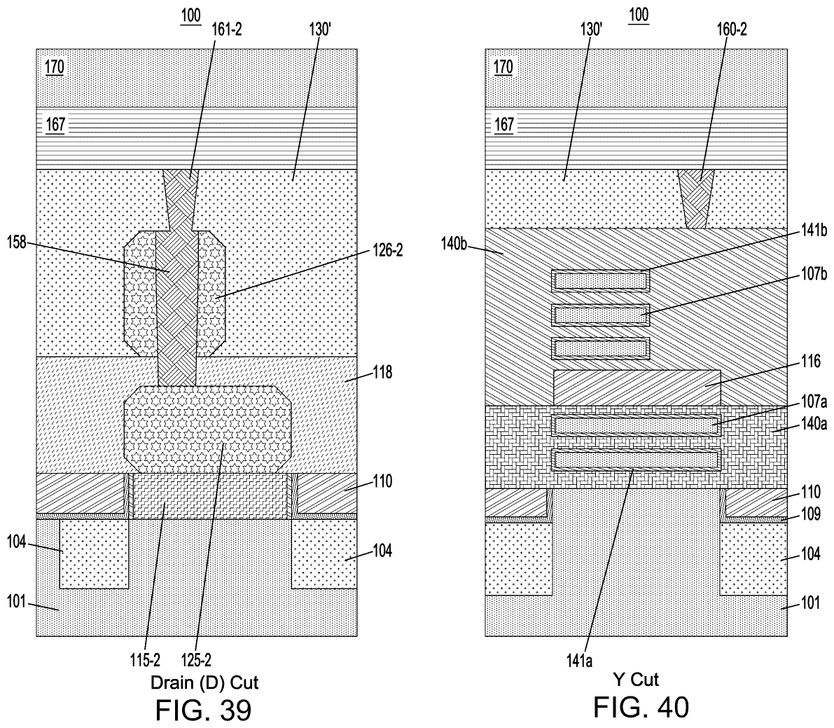

Referring to FIGS. 37-40, frontside BEOL interconnects 167 are formed on the third ILD layer 130′. Wires (not shown) may extend from the frontside BEOL interconnects 167 to deliver gate voltages to the frontside gate contacts 160 and to deliver source/drain signal voltages to the frontside source/drain contacts 161.

A carrier wafer 170 is bonded to the frontside BEOL interconnects 167. The frontside BEOL interconnects 167 include various BEOL interconnect structures which may electrically connect to the frontside gate contacts 160 and frontside source/drain contacts 161. The carrier wafer 170 may be formed of materials similar to that of the semiconductor substrate 101, and may be formed over the frontside BEOL interconnects 167 using a wafer bonding process, such as dielectric-to-dielectric bonding.

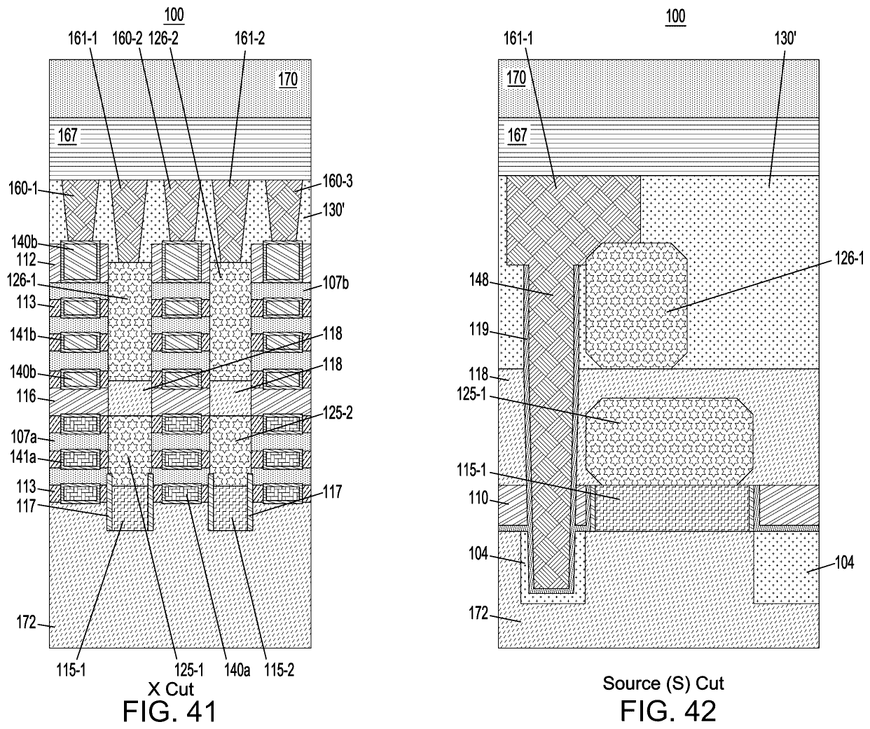

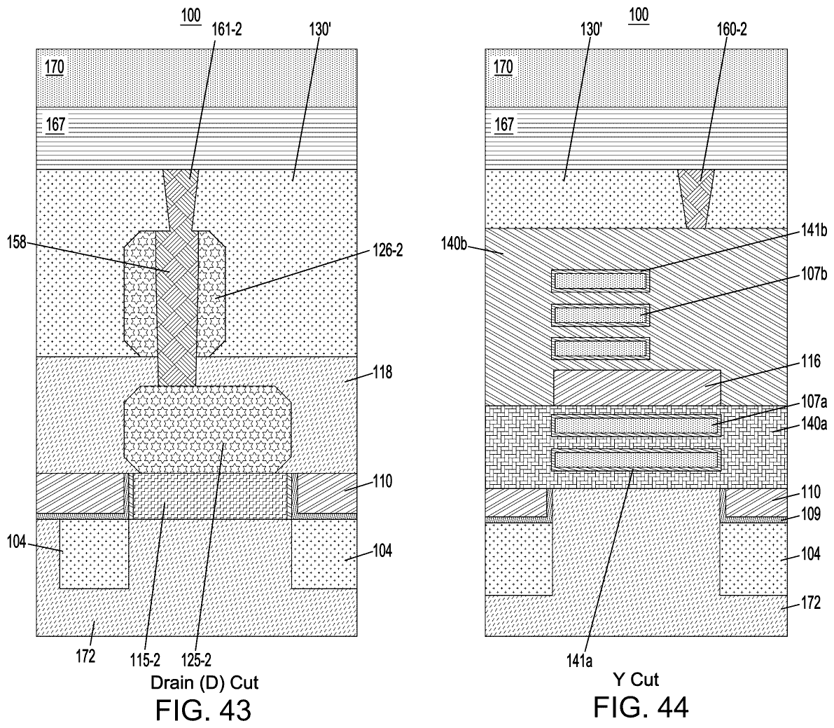

Referring to FIGS. 41-44, using the carrier wafer 170, the semiconductor structure 100 may be “flipped” (e.g., rotated 180 degrees) so that the structure is inverted. In addition, the semiconductor substrate 101 is removed from the backside of the semiconductor structure 100. For example, the semiconductor substrate 101 is selectively etched with an etchant that selectively etches silicon with respect to other exposed materials, wherein portions of the isolation regions 104, the dual dielectric layers and the sacrificial placeholder layers 115 are exposed. A backside ILD layer 172 is deposited to fill in areas formerly occupied by the semiconductor substrate 101. The backside ILD layer 172 is deposited using deposition techniques such as, for example, CVD, PECVD, RFCVD, PVD, ALD, MBD, PLD, and/or LSMCD, followed by a planarization process. The backside ILD layer 172 may comprise, for example, SiOₓ, SiOC, SiOCN or some other dielectric.

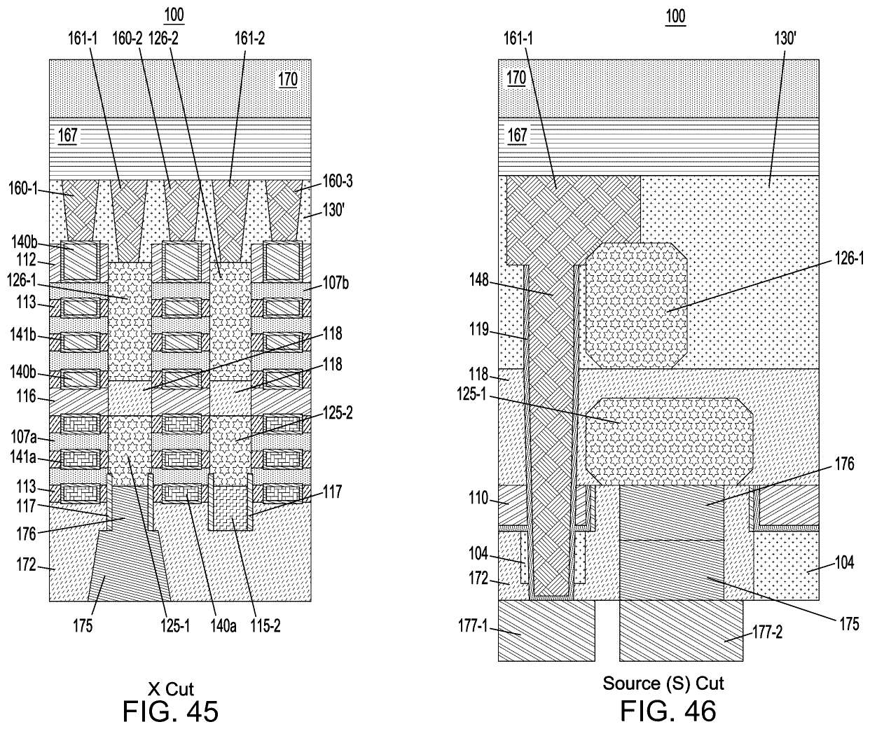

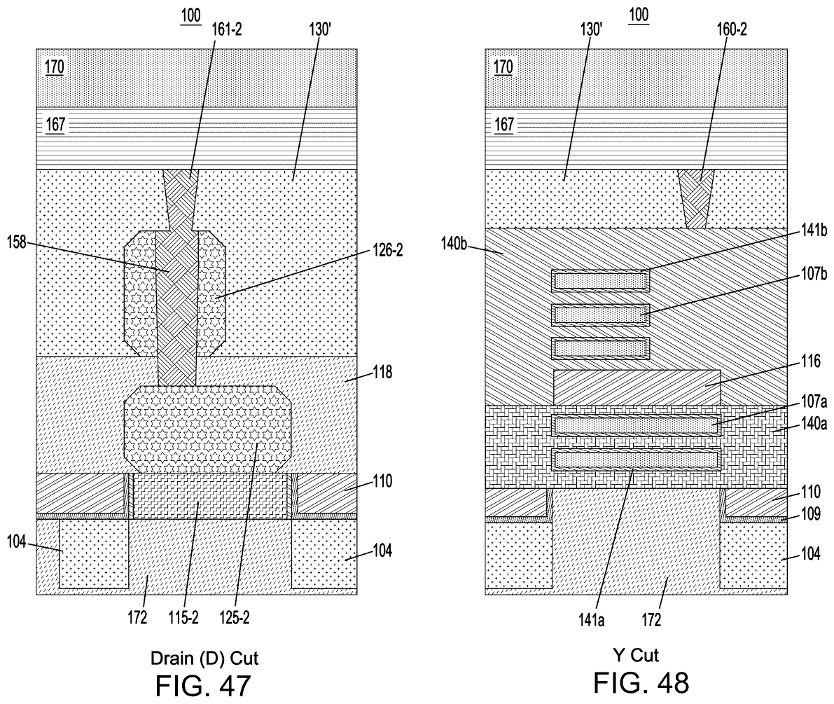

Referring to FIGS. 45-48, portions of the backside ILD layer 172 are etched to expose the sacrificial placeholder layer 115-1, which is selectively removed using, for example, a selective dry or wet etch process. A first backside source/drain contact 176 is formed in the backside ILD layer 172 in the opening left by the removal of the sacrificial placeholder layer 115-1, and a second backside source/drain contact 175 is formed on the first backside source/drain contact 176 in a corresponding opening in the backside ILD layer 172. Metal layers are deposited in the openings to form the first and second backside source/drain contacts 176 and 175. The metal layers comprise, for example, a conductive metal fill layer, such as W, Mo, Co, Ru, etc., and can be deposited using, for example, a deposition technique such as CVD, PECVD, RFCVD, PVD, ALD, MBD, PLD, LSMCD, sputtering and/or plating, followed by a planarization process such as, CMP to remove excess portions of the metal layers from on top of the backside ILD layer 172.

As can be seen in FIG. 46, portions of the backside ILD layer and isolation region 104 are etched to expose the via conductive layer 148, which is connected to a first backside metallization contact 177-1, which provides, for example, a ground voltage connection.

The first backside source/drain contact 176 contacts a backside of the bottom source/drain region 125-1. The second backside contact 175 is connected to a second backside metallization contact 177-2 which supplies, for example, a source/drain voltage (e.g., VDD) to the second backside source/drain contact 175 and first backside source/drain contact 176 from, for example, a backside power delivery network (BSPDN) (also referred to herein as backside interconnects) (not shown) formed on the backside ILD layer 172 and on the first and second backside metallization contacts 177-1 and 177-2. The BSPDN includes various BSPDN structures such as, but not necessarily limited to, interconnects in a power supply path from voltage regulator modules (VRMs) to circuits. The interconnects can comprise, for example, power and ground planes in circuit boards, cables, connectors and capacitors associated with a power supply. Backside power delivery prevents BEOL routing congestion, resulting in power performance benefits.

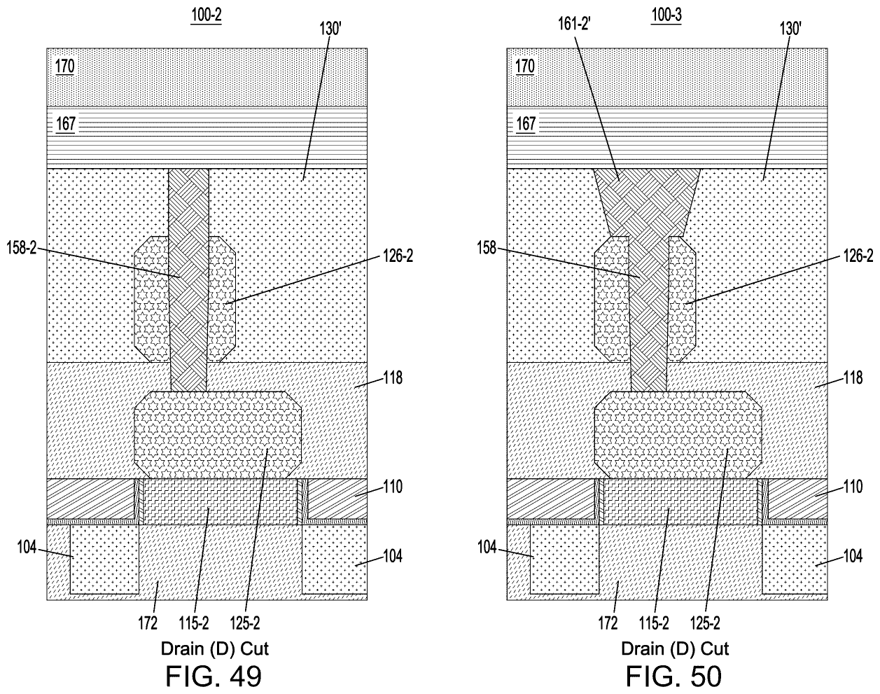

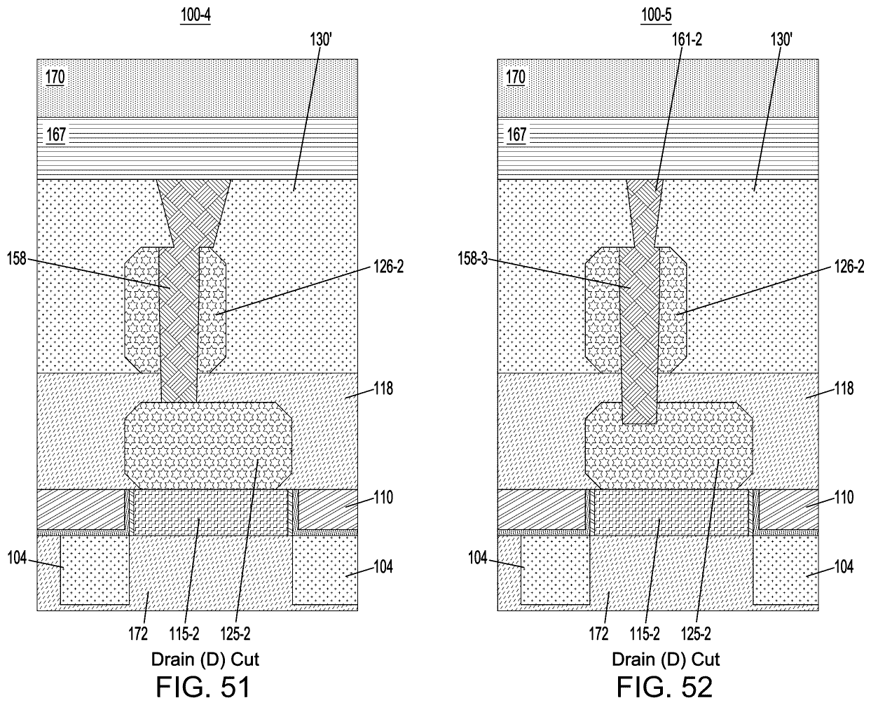

FIGS. 49-56 depict cross-sectional views of drain regions including alternative frontside drain contact configurations and/or alternative epitaxial region contact structure configurations. For example, in the semiconductor structure 100-2 in FIG. 49, the second source/drain contact 161-2 is omitted since a first alternative drain epitaxial region contact structure 158-2 extends through the second and third ILD layers 130 and 130′ directly from the BEOL interconnects 167. In the semiconductor structure 100-3 in FIG. 50, a first alternative second source/drain contact 161-2′ is larger in width (horizontal direction in FIG. 50) than the second source/drain contact 161-2 and extends onto upper surfaces of the top source/drain region 126-2 on two sides of the drain epitaxial region contact structure 158. In the semiconductor structure 100-4 in FIG. 51, a second alternative second source/drain contact 161-2″ is also larger in width (horizontal direction in FIG. 51) than the second source/drain contact 161-2 and is offset with respect to the second source/drain contact 161-2, extending onto an upper surface of the top source/drain 126-2 on one side of the drain epitaxial region contact structure 158.

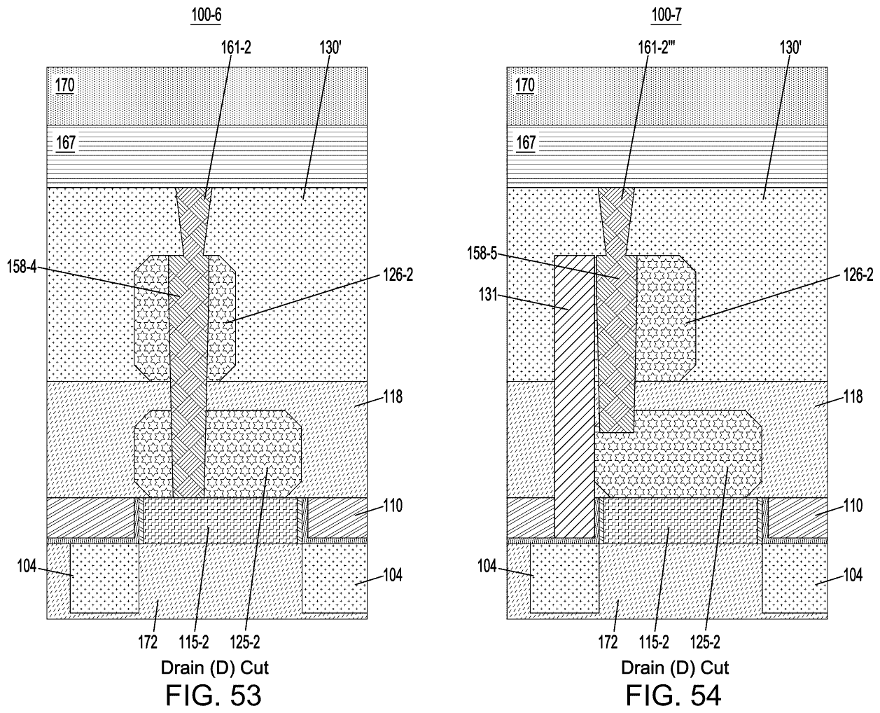

In the semiconductor structure 100-5 in FIG. 52, a second alternative drain epitaxial region contact structure 158-3 extends through the first ILD layer 118 to penetrate into an upper portion of the bottom source/drain region 125-2 instead of landing on a top surface of the bottom source/drain region 125-2. In the semiconductor structure 100-6 in FIG. 53, a third alternative drain epitaxial region contact structure 158-4 extends through the bottom source/drain region 125-2 to land on a top surface of the second sacrificial placeholder layer 115-2 instead of landing on a top surface of the bottom source/drain region 125-2. In the semiconductor structure 100-7 in FIG. 54, a fourth alternative drain epitaxial region contact structure 158-5 aligns with an edge (e.g., left edge in FIG. 54) of the top source/drain region 126-2, wherein the alignment is accomplished by forming a dielectric bar layer 131 along the edge of the top source/drain region 126-2. In addition, the fourth alternative drain epitaxial region contact structure 158-5 extends through the first ILD layer 118 to penetrate into an upper portion of the bottom source/drain region 125-2 instead of landing on a top surface of the bottom source/drain region 125-2. Also, in the semiconductor structure 100-7, a third alternative second source/drain contact 161-2′″ is formed to line up with the fourth alternative drain epitaxial region contact structure 158-5.

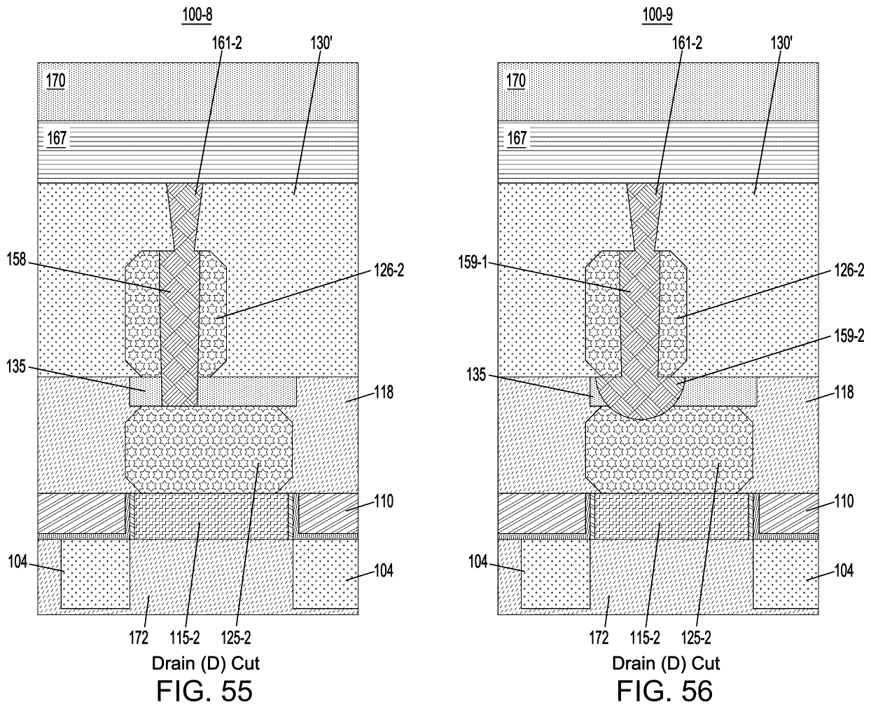

In the semiconductor structure 100-8 in FIG. 55, a semiconductor placeholder layer 135 is formed between the top source/drain region 126-2 and bottom source/drain region 125-2. The semiconductor placeholder layer 135 includes, for example, silicon nitride (Si₃N₄), aluminum oxide (Al₂O₃), aluminum nitride (AlN), etc. In this embodiment, the drain epitaxial region contact structure 158 is formed through the semiconductor placeholder layer 135 to land on and contact a top surface of the bottom source/drain region 125-2. In the semiconductor structure 100-9 in FIG. 56, a fifth alternative drain epitaxial region contact structure includes a first portion 159-1 and a second portion 159-2. The first portion 159-1 has a first width (horizontal direction in FIG. 56), and the second portion 159-2 has a second width (horizontal direction in FIG. 56) greater than the first width. The second portion has a different shape (e.g., semi-circular) than the first portion 159-1 (e.g., rectangular). The second portion 159-2 penetrates into an upper portion of the bottom source/drain region 125-2 is formed by undercutting the semiconductor placeholder layer 135. The first portion 159-1 is formed through the top source/drain region 126-2.

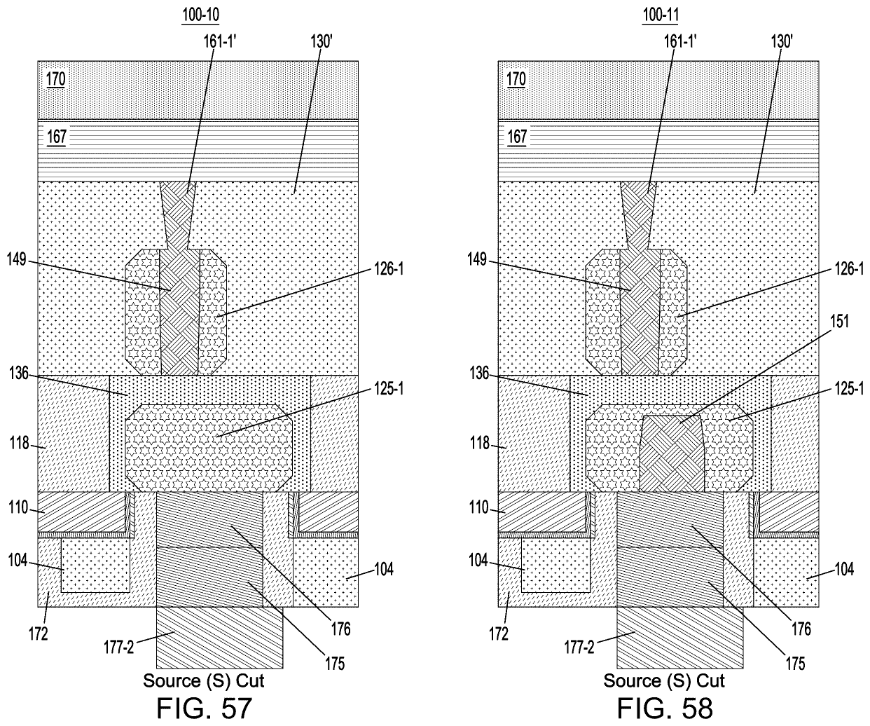

FIGS. 57-60 depict cross-sectional views of source regions including an alternative frontside source contact configuration and alternative backside epitaxial region contact structure configurations. For example, in the semiconductor structure 100-10 in FIG. 57, a source epitaxial region contact structure 149 is formed in the top source/drain region 126-1, which, as noted herein above, is a source region in illustrative embodiments. The source epitaxial region contact structure 149 may comprise the same materials as or similar materials to the materials of the drain epitaxial region contact structure 158. The semiconductor structure 100-10 further includes a dielectric etch stop layer 136 formed on a top surface and around side surfaces of the bottom source/drain region 125-1, which, as noted herein above, is also a source region in illustrative embodiments. The dielectric etch stop layer 136 includes, for example, Aluminum Oxide Al₂O₃, Aluminum Nitride (AlN), Silicon Nitride (Si₃N₄), etc. The semiconductor structure 100-10 further includes an alternative first frontside source/drain contact 161-1′, which is formed through the second and third ILD layers 130 and 130′ to land on and contact the source epitaxial region contact structure 149. The source epitaxial region contact structure 149 is formed through the top source/drain region 126-1 to land on and contact a top surface of the dielectric etch stop layer 136. The dielectric etch stop layer 136 stops the etching of the top source/drain region 126-1 when forming the opening in which the source epitaxial region contact structure 149 is formed. The semiconductor structure 100-11 in FIG. 58 is similar to the semiconductor structure 100-10, except that a backside source epitaxial region contact structure 151 is formed in the bottom source/drain region 125-1. The backside source epitaxial region contact structure 151 may comprise the same materials as or similar materials to the materials of the drain epitaxial region contact structure 158. The second backside source/drain contact 175 is connected to the backside source epitaxial region contact structure 151 through the first backside source/drain contact 176, which contacts the backside source epitaxial region contact structure 151.

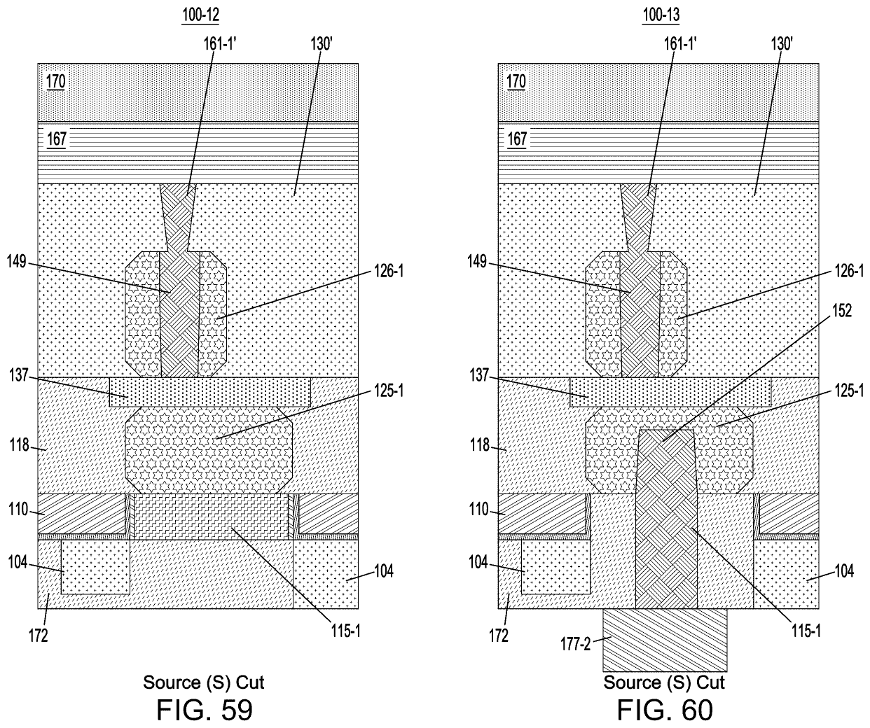

The semiconductor structure 100-12 in FIG. 59 is similar to the semiconductor structure 100-10 in FIG. 57, except that, unlike the dielectric etch stop layer 136, a dielectric etch stop layer 137 formed on top a surface, but not around side surfaces of the bottom source/drain region 125-1. In addition, unlike the semiconductor structure 100-10 in FIG. 57, the sacrificial placeholder layer 115-1 in FIG. 59 remains. The semiconductor structure 100-13 in FIG. 60 is similar to the semiconductor structure 100-12 in FIG. 59, except that an alternative backside source epitaxial region contact structure 152 is formed in the bottom source/drain region 125-1. The alternative backside source epitaxial region contact structure 152 may comprise the same materials as or similar materials to the materials of the drain epitaxial region contact structure 158. The alternative backside source epitaxial region contact structure 152 extends directly from the second backside metallization contact 177-2 through the backside ILD layer 172 and into the bottom source/drain region 125-1.

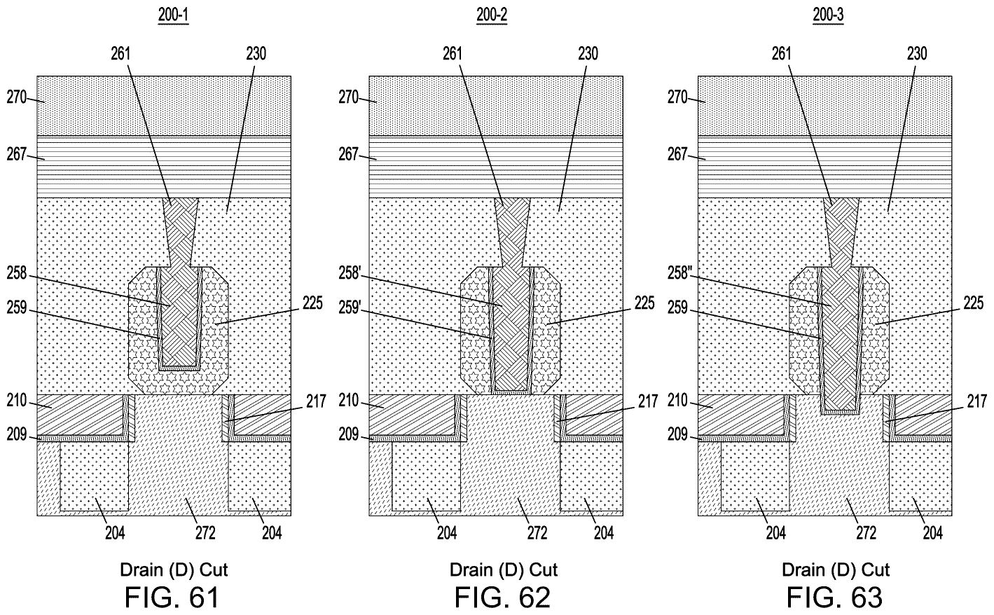

FIGS. 61-63 depict cross-sectional views of drain regions including different epitaxial region contact structure configurations for a non-stacked FET. In the semiconductor structures 200-1, 200-2 and 200-3 described in connection with FIGS. 61-63, the same or similar reference numbers are used to denote the same or similar features, elements, or structures as in the semiconductor structure 100, and thus, a detailed explanation of the same or similar features, elements, or structures is not repeated for the semiconductor structures 200-1, 200-2 and 200-3.

The semiconductor structures 200-1, 200-2 and 200-3 illustrate a source/drain region 225, which in illustrative embodiments, is a drain region for a non-stacked FET. Similar to the semiconductor structure 100, the semiconductor structures 200-1 to 200-3 each include isolation layers 204, nitride layers 209, oxide layers 210, dielectric spacers 217, an ILD layer 230, a source/drain contact 261, BEOL interconnects 267, a carrier wafer 270 and a backside ILD layer 272. In the semiconductor structure 200-1, a first frontside drain epitaxial contact structure is formed partially through a source/drain region 225 and includes a first conductive layer 258 and first liner layer 259. The first conductive layer 258 includes, for example, W, Mo, Co, Ru, etc., and can be deposited using, for example, a deposition technique such as CVD, PECVD, RFCVD, PVD, ALD, MBD, PLD, LSMCD, sputtering and/or plating. The first conductive layer 258 is formed on the first liner layer 259, which is the similar to the via liner layer 119 (e.g., Ti or TiN). The first liner layer 259 is optional. In the semiconductor structure 200-2, a second frontside drain epitaxial contact structure is formed through the source/drain region 225 down to the backside ILD layer 272 and includes a second conductive layer 258′ and a second liner layer 259′. The compositions and configurations of the second conductive layer 258′ and the second liner layer 259′ are the same as or similar to the compositions and configurations of the first conductive layer 258 and the first liner layer 259, except that the second frontside drain epitaxial contact structure is formed through the source/drain region 225 and contacts the backside ILD layer 272. In the semiconductor structure 200-3, a third frontside drain epitaxial contact structure is formed through the source/drain region 225 and penetrates into the backside ILD layer 272, and includes a third conductive layer 258″ and a third liner layer 259″. The compositions and configurations of the third conductive layer 258″ and the third liner layer 259″ are the same as or similar to the compositions and configurations of the first conductive layer 258 and the first liner layer 259, except that the third frontside drain epitaxial contact structure is formed through the source/drain region 225 and penetrates the backside ILD layer 272.

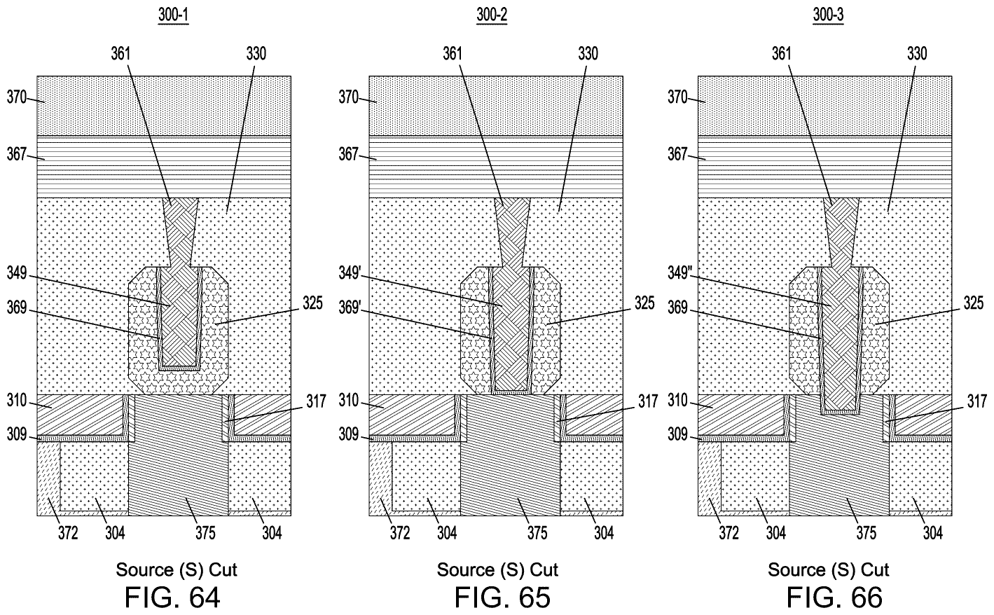

FIGS. 64-68 depict cross-sectional views of source regions including different epitaxial region contact structure configurations for a non-stacked FET. In the semiconductor structures 300-1, 300-2 and 300-3 described in connection with FIGS. 64-66, the same or similar reference numbers are used to denote the same or similar features, elements, or structures as in the semiconductor structure 100, and thus, a detailed explanation of the same or similar features, elements, or structures is not repeated for the semiconductor structures 300-1, 300-2 and 300-3.

The semiconductor structures 300-1, 300-2 and 300-3 illustrate a source/drain region 325, which in illustrative embodiments, is a source region for a non-stacked FET. Similar to the semiconductor structure 100, the semiconductor structures 300-1 to 300-3 each include isolation layers 304, nitride layers 309, oxide layers 310, dielectric spacers 317, an ILD layer 330, a source/drain contact 361, BEOL interconnects 367, a carrier wafer 370, a backside ILD layer 372 and a backside source/drain contact 375. In the semiconductor structure 300-1, a first frontside source epitaxial contact structure is formed partially through a source/drain region 325 and includes a first source conductive layer 349 and first source liner layer 369. The first source conductive layer 349 includes, for example, W, Mo, Co, Ru, etc., and can be deposited using, for example, a deposition technique such as CVD, PECVD, RFCVD, PVD, ALD, MBD, PLD, LSMCD, sputtering and/or plating. The first source conductive layer 349 is formed on the first source liner layer 369, which is the similar to the via liner layer 119 (e.g., Ti or TiN). The first source liner layer 369 is optional. In the semiconductor structure 300-2, a second frontside source epitaxial contact structure is formed through the source/drain region 325 down to the backside source/drain contact 375 and includes a second source conductive layer 349′ and a second source liner layer 369′. The compositions and configurations of the second source conductive layer 349′ and the second source liner layer 369′ are the same as or similar to the compositions and configurations of the first source conductive layer 349 and the first source liner layer 369, except that the second frontside source epitaxial contact structure is formed through the source/drain region 325 and contacts the backside source/drain contact 375. In the semiconductor structure 300-3, a third frontside source epitaxial contact structure is formed through the source/drain region 325 and penetrates into the backside source/drain contact 375, and includes a third source conductive layer 349″ and a third source liner layer 269″. The compositions and configurations of the third source conductive layer 349″ and the third source liner layer 369″ are the same as or similar to the compositions and configurations of the first source conductive layer 349 and the first source liner layer 369, except that the third frontside drain epitaxial contact structure is formed through the source/drain region 325 and penetrates the backside source/drain contact 375.

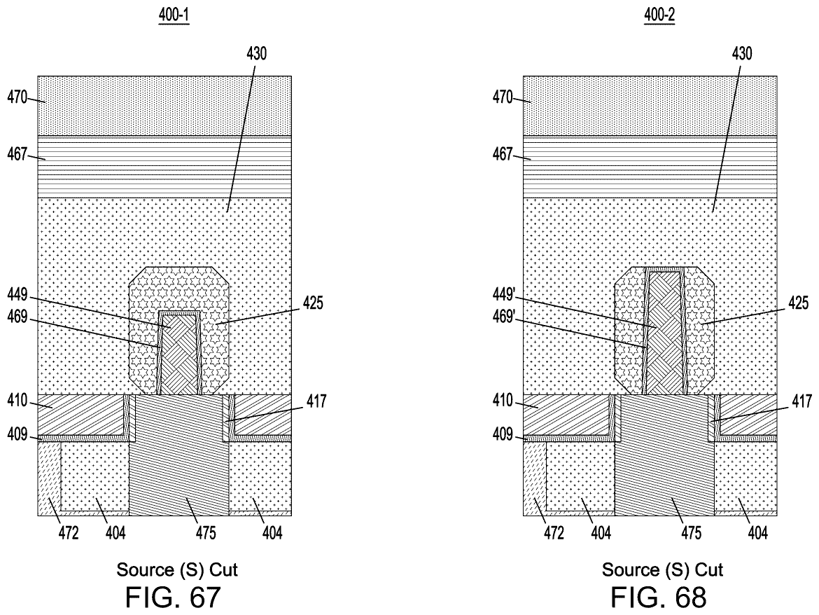

Referring to FIGS. 67 and 68, in the semiconductor structures 400-1 and 400-2, the same or similar reference numbers are used to denote the same or similar features, elements, or structures as in the semiconductor structure 100, and thus, a detailed explanation of the same or similar features, elements, or structures is not repeated for the semiconductor structures 400-1 and 400-2.

The semiconductor structures 400-1 and 400-2 illustrate a source/drain region 425, which in illustrative embodiments, is a source region for a non-stacked FET. Similar to the semiconductor structure 100, the semiconductor structures 400-1 and 400-2 each include isolation layers 404, nitride layers 409, oxide layers 410, dielectric spacers 417, an ILD layer 430, BEOL interconnects 467, a carrier wafer 470, a backside ILD layer 472 and a backside source/drain contact 475. In the semiconductor structure 400-1, a first backside source epitaxial contact structure is formed partially through a source/drain region 425 from a backside of the semiconductor structure 400-1, and includes a first backside source conductive layer 449 and first backside source liner layer 469. The first backside source conductive layer 449 includes, for example, W, Mo, Co, Ru, etc., and can be deposited using, for example, a deposition technique such as CVD, PECVD, RFCVD, PVD, ALD, MBD, PLD, LSMCD, sputtering and/or plating. The first backside source conductive layer 449 is formed on the first backside source liner layer 469, which is the similar to the via liner layer 119 (e.g., Ti or TiN). The first backside source liner layer 469 is optional. A base portion of the first backside source epitaxial contact structure is disposed on and contacts the backside source/drain contact 375. In the semiconductor structure 400-2, a second backside source epitaxial contact structure is formed through the source/drain region 325 to a top surface of the source/drain region 425 bordering the ILD layer 430, and includes a second backside source conductive layer 449′ and a second backside source liner layer 469′. The compositions and configurations of the second backside source conductive layer 449′ and the second backside source liner layer 469′ are the same as or similar to the compositions and configurations of the first backside source conductive layer 449 and the first backside source liner layer 469, except that the second backside source epitaxial contact structure is formed through the source/drain region 425 to a top surface of the source/drain region 425.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

As noted above, the embodiments provide structures for and techniques for forming epitaxial region contact structures for FETs. In the illustrative embodiments, a stacked FET structure is formed with a top FET and a bottom FET drain connection through a top epitaxial source/drain region to a bottom source/drain epitaxial region. In some embodiments, the top and bottom FET and/or epitaxial region widths may or may not be the same. In illustrative embodiments, heights of the contact structures formed in the epitaxial source/drain regions can be less than, equal to or greater than the heights of the corresponding epitaxial source/drain regions. The contact structures can be formed from a frontside or backside of a wafer. In some embodiments, the source/drain contacts extending between a voltage source and the contact structures partially overlap or completely overlap the contact structures formed in the source/drain epitaxial regions. In some embodiments, the contact structures may include all metal material or a combination of metal and non-metal (e.g., dielectric or semiconductor) material.

Advantageously, the illustrative embodiments provide reduced capacitance between drains and gates, top FET contact resistance gain, and stress gains for top FETs without compromising bottom FET performance.

In one embodiment, a semiconductor device includes a first transistor including a first drain region, and a second transistor including a second drain region, wherein the second transistor is stacked over the first transistor. A contact structure is disposed through the second drain region, wherein the contact structure contacts the first drain region.

The contact structure may include at least one conductive material, wherein the first drain region and the second drain region respectively comprise epitaxial layers. The first drain region and the second drain region may have different widths from each other. The contact structure may be disposed on a top surface of the first drain region. A portion of the contact structure may be disposed in at least part of the first drain region. A portion of the contact structure may be disposed through the first drain region. The contact structure may be aligned with at least one edge of the second drain region.

The semiconductor device may further include a dielectric layer between the first drain region and the second drain region, wherein the contact structure is disposed through the dielectric layer. The contact structure may be connected to a voltage source disposed on a first side of the semiconductor over the second transistor, and the contact structure may be connected to the voltage source through a contact element disposed between the contact structure and the voltage source.

The contact structure may have more than one width. The first transistor may further include a first source region and the second transistor may further include a second source region. A via may be disposed on a side of the first source region and the second source region, wherein the via is connected to the second source region, and to a voltage source on a backside of the semiconductor device.

In another embodiment, a semiconductor device includes a first field-effect transistor including a first epitaxial region, a second field-effect transistor including a second epitaxial region, wherein in the second epitaxial region is stacked over the first epitaxial region, and a contact structure disposed through the second epitaxial region, wherein the contact structure is connected to the first epitaxial region.

The contact structure may be disposed on a top surface of the first epitaxial region. A portion of the contact structure may be disposed in at least part of the first epitaxial region. A portion of the contact structure may be disposed through the first epitaxial region.

In another embodiment, a semiconductor device includes at least one field-effect transistor including a source region and a drain region, and a contact structure disposed in at least one of the source region and the drain region. The contact structure includes at least one conductive material, and the source region and the drain region respectively comprise epitaxial layers.

The contact structure may be connected to a voltage source on at least one of a frontside and a backside of the semiconductor device. The at least one field-effect transistor may be stacked on an additional field-effect transistor. The additional field-effect transistor may include an additional source region and an additional drain region. The contact structure may be disposed through the drain region of the at least one field-effect transistor and may contact the additional drain region.

The semiconductor device may further include a dielectric layer between the drain region of the at least one field-effect transistor and the additional drain region, wherein the contact structure is disposed through the dielectric layer.

It should be understood that the various layers, structures, and regions shown in the figures are schematic illustrations that are not drawn to scale. In addition, for case of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a first transistor comprising a first drain region;
a second transistor comprising a second drain region, wherein the second transistor is stacked over the first transistor; and
a contact structure disposed through the second drain region, wherein the contact structure contacts the first drain region.

2. The semiconductor device of claim 1, wherein the contact structure comprises at least one conductive material, and wherein the first drain region and the second drain region respectively comprise epitaxial layers.

3. The semiconductor device of claim 1, wherein the first drain region and the second drain region have different widths from each other.

4. The semiconductor device of claim 1, wherein the contact structure is disposed on a top surface of the first drain region.

5. The semiconductor device of claim 1, wherein a portion of the contact structure is disposed in at least part of the first drain region.

6. The semiconductor device of claim 1, wherein a portion of the contact structure is disposed through the first drain region.

7. The semiconductor device of claim 1, wherein the contact structure is aligned with at least one edge of the second drain region.

8. The semiconductor device of claim 1, further comprising a dielectric layer between the first drain region and the second drain region, wherein the contact structure is disposed through the dielectric layer.

9. The semiconductor device of claim 1, wherein:
the contact structure is connected to a voltage source disposed on a first side of the semiconductor over the second transistor; and
the contact structure is connected to the voltage source through a contact element disposed between the contact structure and the voltage source.

10. The semiconductor device of claim 1, wherein the contact structure has more than one width.

11. The semiconductor device of claim 1, wherein the first transistor further comprises a first source region and the second transistor further comprises a second source region.

12. The semiconductor device of claim 11, further comprising a via disposed on a side of the first source region and the second source region, wherein the via is connected to the second source region, and to a voltage source on a backside of the semiconductor device.

13. A semiconductor device comprising:
a first field-effect transistor comprising a first epitaxial region;
a second field-effect transistor comprising a second epitaxial region, wherein in the second epitaxial region is stacked over the first epitaxial region; and
a contact structure disposed through the second epitaxial region, wherein the contact structure is connected to the first epitaxial region.

14. The semiconductor device of claim 13, wherein the contact structure is disposed on a top surface of the first epitaxial region.

15. The semiconductor device of claim 13, wherein a portion of the contact structure is disposed in at least part of the first epitaxial region.

16. The semiconductor device of claim 1, wherein a portion of the contact structure is disposed through the first epitaxial region.

17. A semiconductor device comprising:
at least one field-effect transistor comprising a source region and a drain region; and
a contact structure disposed in at least one of the source region and the drain region;
wherein the contact structure comprises at least one conductive material; and
wherein the source region and the drain region respectively comprise epitaxial layers.

18. The semiconductor device of claim 17, wherein the contact structure is connected to a voltage source on at least one of a frontside and a backside of the semiconductor device.

19. The semiconductor device of claim 18, wherein:
the at least one field-effect transistor is stacked on an additional field-effect transistor;
the additional field-effect transistor comprises an additional source region and an additional drain region; and
the contact structure is disposed through the drain region of the at least one field-effect transistor and contacts the additional drain region.

20. The semiconductor device of claim 19, further comprising a dielectric layer between the drain region of the at least one field-effect transistor and the additional drain region, wherein the contact structure is disposed through the dielectric layer.
